(19) United States
(12) Patent Application Publication
(10) Pub. No.: US 2025/0123913 A1
(43) Pub. Date: Apr. 17, 2025

(54) CLOUD-BASED DIGITAL TWIN AND VIRTUAL DEVICE SYSTEM FOR EFFICIENT AUDIO, VIDEO, AND CONTROL SYSTEM AND DEVICE MANAGEMENT AND TESTING

(71) Applicant: QSC, LLC, Costa Mesa, CA (US)

(72) Inventors: Matthew SKOGMO; Gerrit Rosenboom, Longmont, CO (US); John Bayard Britton, Longmont, CO (US); John Dunn, Denver, CO (US)

(73) Assignee: QSC, LLC, Costa Mesa, CA (US)

(21) Appl. No.: 18/913,717

(22) Filed: Oct. 11, 2024

Related U.S. Application Data
(60) Provisional application No. 63/590,394, filed on Oct. 13, 2023.
(60) Provisional application No. 63/590,399, filed on Oct. 13, 2023.
(60) Provisional application No. 63/590,401, filed on Oct. 13, 2023.

(51) Int. Cl. G06F 11/00; G06F 11/34

(52) U.S. Cl. CPC G06F 11/008; G06F 11/3457

(57) ABSTRACT

A method of monitoring behavior of an AVC system that may include communicatively connecting one or more devices to a server of a cloud platform, creating one or more device digital twins, synchronizing the device digital twins to the devices, creating one or more space digital twins of the physical spaces that the devices are located in, synchronizing the space digital twins to a corresponding physical space, analyzing data associated with the one or more devices to create an output indicative of at least one of the health and reliability of the one or more devices, usage and operational status of the physical space or presenting the output on a computing device.

### CROSS REFERENCE TO RELATED APPLICATIONS

This application claims the benefit of U.S. Provisional Application Ser. No. 63/590,394, filed Oct. 13, 2023, U.S. Provisional Application Ser. No. 63/590,399, filed Oct. 13, 2023, and 63/590,401, filed Oct. 13, 2023, the content of which is hereby incorporated by reference in its entirety.

### TECHNICAL FIELD

The present disclosure relates to an audio, video, and control (AVC) system. In particular, the present disclosure relates to a cloud-based AVC system.

### BACKGROUND

AVC systems are typically configured to interconnect, operate, and manage audio systems, video systems, and/or control systems for a particular location, such as a conference room, a classroom, and/or a convention center. AVC system devices may include, but not be limited to, video cameras, microphones (e.g., dynamic beamforming microphones and static microphones), speakers, displays and monitors, amplifiers, processing cores, and/or other devices.

AVC systems may be sophisticated setups designed to facilitate and manage audio and video signals from multiple devices in multiple locations and may interact with other systems in other locations. In conventional systems, system design, set-up, testing, and deployment can be complex, time-consuming, and expensive. For example, there may be significant upfront costs related to the purchase of physical devices during the design and testing phases. Further, system testing is required to mitigate risks associated with, but not limited to, the predictability of a software upgrades, security vulnerabilities, the integration of a specific physical device with other systems and components and addressing and evaluating different use case scenarios and operational conditions.

Thus, there is a need for a flexible, cost conscious, risk-reduced environment for creating sophisticated, well-tuned AVC systems. Accordingly, it may be desirable to provide a cloud-based AVC system that may utilize virtual devices and/or digital twins for prototyping, testing, or final deployment to iterate and refine the system virtually before investing in and deploying physical devices.

### SUMMARY

The present disclosure provides a cloud-based audio, video, and control (AVC) system and methods associated with the operation therewith. In some embodiments, the cloud-based AVC system may include a computing device, a cloud platform, a digital twin platform as part of the cloud platform, and one or more physical devices.

In some embodiments, the present disclosure provides an audio, video, and control system including one or more devices communicatively connected to a server on a cloud platform, one or more device digital twins of the one or more devices. In some embodiments, the one or more devices may include at least one of a camera, a microphone, a soundbar, or a processor.

In some embodiments, the audio, video, and control system may include one or more device digital twins of the one or more devices, wherein the one or more device digital twins may reside on the cloud platform. In some embodiments, the one or more device digital twins may be synchronized with the one or more devices to collect data (e.g., telemetry data) associated with the one or more devices.

In some embodiments, the audio, video, and control system may include one or more space digital twins of one or more physical spaces that the one or more devices are located in, wherein the one or more space digital twins may reside on the cloud platform. In some embodiments, each of the one or more space digital twins may be synchronized with the one or more devices located within the corresponding physical space to collect the data associated with the one or more devices.

In some embodiments, the audio, video, and control system may include a memory coupled to the server comprising instructions executable by the server, wherein the server is operable when executing the instructions to perform various functions.

In some embodiments, the server may be operable when executing the instructions to create one or more device digital twins of the one or more physical devices.

In some embodiments, the server may be operable when executing the instructions to synchronize each of the one or more device digital twins to a corresponding device of the one or more physical devices such that the one or more device digital twins receive data associated with the one or more devices.

In some embodiments, the server may be operable when executing the instructions to create one or more space digital twins of one or more physical spaces that the one or more devices are located in.

In some embodiments, the server may be operable when executing the instructions to synchronize each of the one or more space digital twins to one or more of the devices that are located in the corresponding physical space such that the one or more space digital twins receive the data associated with the one or more devices.

In some embodiments, the server may be operable when executing the instructions to analyze the data associated with the one or more devices and the one or more physical spaces to create an output indicative of at least one of the health of one or more of the devices, the reliability of one or more of the devices, the usage of the physical space, or the operational status of the physical space.

In some embodiments, the server may be operable when executing the instructions to cause the output to be presented to a computing device, wherein the output includes at least one of a representation of the health of the physical device, a representation of the reliability of the physical device, a representation of the usage of the physical space, or a representation of the operational status of the physical space.

In some embodiments, the server may be operable when executing the instructions to retrieve historical data associated with the one or more devices and the one or more physical spaces from a cloud database for analysis.

In some embodiments, the data associated with the physical space of the one or more devices may include at least one of space occupancy, space people count, space capacity, organization average occupancy, organization average people count, organizational average percent of volume, cloud platform average occupancy, cloud platform average people count, or cloud platform average percent of capacity.

In some embodiments, the data associated with the one or more physical devices may include at least one of system alerts, system average alerts, organization average system alerts, or space business hours.

In some embodiments, the one or more physical spaces may include one or more of a geographical region, a building, a floor of the building, a room, a ceiling, and a wall.

In some embodiments, the server may be operable when executing the instructions to receive ontological data from the one or more devices.

In some embodiments, the server may be operable when executing the instructions to create an ontological framework with classifications of the ontological data of at least one of assets, systems and organization of systems, geographical regions, people and organizations of people, or monitor points and controls.

In some embodiments, the server may be operable when executing the instructions to cause a representation of the ontological framework to be presented to a computing device.

In some embodiments, the ontological framework may include a knowledge graph.

In some embodiments, the server may be operable when executing the instructions to create a map displaying markers indicating a location of one or more of the physical spaces and an operational status of the one or more devices in the one or more physical spaces and to cause the map to be presented to a computer device.

In some embodiments, the map may display one of a region, a building, a floor of the building, and a room.

In some embodiments, the server may be operable when executing the instructions to integrate the one or more device digital twins with a preexisting ontology stored in a database on the cloud platform.

In some embodiments, the present disclosure provides a method of monitoring behavior of an audio, video, and control system. In some embodiments, the method may include communicatively connecting one or more devices of the audio, video, and control system to a server of a cloud platform.

In some embodiments, the method may include creating, by the server, one or more device digital twins of the one or more devices.

In some embodiments, the method may include synchronizing, by the server, each of the one or more device digital twins to a corresponding device of the one or more devices such that each of the one or more device digital twins receives data (e.g., telemetry data) from the corresponding device.

In some embodiments, the method may include creating, by the server, one or more space digital twins of one or more physical spaces that the one or more devices are located in.

In some embodiments, the method may include synchronizing, by the server, each of the one or more space digital twins to a corresponding physical space such that each of the one or more space digital twins receives data (e.g., telemetry data) from one or more of the devices located within corresponding physical space.

In some embodiments, the method may include analyzing, by the server, the data associated with the one or more devices and the one or more physical spaces to create an output indicative of at least one of the health of one or more of the physical devices, the reliability of one or more of the physical devices, the usage of the physical space, or an operational status of the physical space.

In some embodiments, the method may include causing, by the server, the output to be presented to a computing device, wherein the output may include at least one of a representation of the health of the physical device, a representation of the reliability of the physical device, a representation of the usage of the physical space, or a representation of the operational status of the physical space.

In some embodiments, the method may include retrieving, by the server, historical data associated with the one or more devices and the one or more physical spaces from a cloud database for analysis.

In some embodiments, the data associated with the one or more devices located in one of the physical spaces may include at least one of space occupancy, space people count, space capacity, organization average occupancy, organization average people count, organizational average percent of volume, cloud platform average occupancy, cloud platform average people count, or cloud platform average percent of capacity.

In some embodiments, the data associated with the one or more devices may include at least one of system alerts, system average alerts, organization average system alerts, or space business hours.

In some embodiments, the one or more physical spaces may include one or more of a geographical region, a building, a floor of the building, a room, a ceiling, and a wall.

In some embodiments, the method may include receiving, by the server, ontological data from the one or more device, and creating, by the server, an ontological framework with classifications of the ontological data of at least one of assets, systems and organization of systems, geographical regions, people and organizations of people, or monitor points and controls.

In some embodiments, the method may include causing, by the server, a representation of the ontological framework to be presented to a computing device. In some embodiments, the representation of the ontological framework may include a knowledge graph.

In some embodiments, the method may include creating, by the server, a map displaying markers indicating a location of one or more of the physical spaces and a status of the one or more physical devices in the one or more physical spaces and causing the map to be presented to a computer device. In some embodiments, the map may display one of a region, a building, a floor of the building, or a room.

In some embodiments, the method may include integrating, by the server, the one or more device digital twins with a preexisting ontology stored in a database on the cloud platform.

An audio, video, and control system may include one or more devices communicatively connected to a server on a cloud platform and one or more device digital twins of the one or more devices. In some embodiments, the one or more device digital twins may be synchronized with the one or more devices to collect data associated with the one or more devices. In some embodiments, the one or more device digital twins may reside on the cloud platform.

In some embodiments, the audio, video, and control system may include a memory coupled to the server comprising instructions executable by the server. In some embodiments, the server may be operable when executing the instructions to synchronize each of the one or more digital twins to a corresponding device of the one or more devices such that each of the one or more digital twins receives data from the corresponding device.

In some embodiments, the server may be operable when executing the instructions to receive, by the one or more digital twins, ontological data from the one or more devices.

In some embodiments, the server may be operable when executing the instructions to integrate the one or more digital twins with an existing real-estate core ontology stored on the cloud platform, wherein the real-estate core ontology describes the spaces in which the one or more devices are located in.

In some embodiments, the server may be operable when executing the instructions to create an ontological framework based on the ontological data received from the one or more digital twins and ontological data from the real-estate core ontology.

In some embodiments, the server may be operable when executing the instructions to cause a representation of the ontological framework to be presented to a computing device.

In some embodiments, the representation of the ontological framework may include a knowledge graph.

In some embodiments, the representation of the ontological framework may include a topological representation of at least one a grouping and classification of the one or more AVC systems; a grouping and classification of an owner, administrator, or user of each of the one or more AVC systems; and access management to each of the one or more AVC systems.

In some embodiments, the representation may include a world-view representation including at least one of geographical regions, sites, buildings, levels, rooms, or zones in which the one or more devices are located.

In some embodiments, the one or more devices may include at least one of a camera, a microphone, a soundbar, or a processor.

Various aspects of the system, as well as other embodiments, objects, features and advantages of this disclosure, will be apparent from the following detailed description of illustrative embodiments thereof, which is to be read in conjunction with the accompanying drawings.

### BRIEF DESCRIPTION OF THE DRAWINGS

FIG. 1 is a diagram illustrating an example cloud-based AVC system, according to embodiments of the present disclosure.

FIGS. 2A-C are diagrams illustrating steps of an AVC setup process using digital twins, according to embodiments of the present disclosure.

FIG. 2D is a diagram illustrating the cloud platform monitoring behavior of a virtual device or digital twin and recording the monitored behavior for analysis and review, according to embodiments of the present disclosure.

FIG. 3 is a block diagram illustrating a digital twin updating a physical, replacement device with settings, parameters, configuration data, and so on stored in the digital twin, according to embodiments of the present disclosure.

FIG. 4 is a diagram illustrating a virtual core capable of processing audio signals, video signals, and control signals captured by physical devices, according to embodiments of the present disclosure.

FIG. 5 is an example diagram illustrating an ontological graph comprising a collection of ontological data in various classifications, and relationships between such, according to embodiments of the present disclosure.

FIG. 6 is an example diagram illustrating a graphical representation of digital twins of the ontological graph of FIG. 5, according to embodiments of the present disclosure.

FIG. 7 is a set of tables listing information stored within respective digital twins and the relationship between such, according to embodiments of the present disclosure.

FIG. 8 is a flowchart illustrating a method for designing and emulating an AVC setup, within a cloud platform, and deploying the AVC setup from the cloud platform to at least one physical device, according to embodiments of the present disclosure.

FIG. 9 is a flowchart illustrating a method for designing and emulating an AVC setup within a cloud platform, and then deploying the AVC setup from the cloud platform to at least one physical device, according to embodiments of the present disclosure.

FIG. 10 is a flowchart illustrating a method for deploying setting information from a digital twin to a replacement physical device, according to embodiments of the present disclosure.

FIG. 11 is a flowchart illustrating a method for redirecting signals to a virtual device upon detecting performance degradation of a physical device, according to embodiments of the present disclosure.

FIG. 12 is a flowchart illustrating a method for emulating a software update on a virtual device prior to deploying the software update to a physical device, according to embodiments of the present disclosure.

FIG. 13 is a flowchart illustrating a method for monitoring behavior of a virtual system and recording such for analysis and review, according to embodiments of the present disclosure.

FIG. 14 is a block diagram illustrating an example computing environment, according to embodiments of the present disclosure.

FIG. 15 is a diagram illustrating an example space panel user interface of the AVC system.

FIG. 16 is a diagram illustrating an example of how an ontology describing the AVC system 1600 may interact or be linked with another existing ontology.

FIG. 17 is a diagram illustrating an example of how an ontology describing one more AVC systems may interact or be linked with another existing ontology.

FIG. 18 is a diagram illustrating the relationships between inventory items of the AVC system 1800 and at least one of their components.

### DETAILED DESCRIPTION

The following detailed description of example implementations of a cloud-based audio, video, and control (AVC) system refers to the accompanying drawings. The same reference numbers in different drawings may identify the same or similar elements.

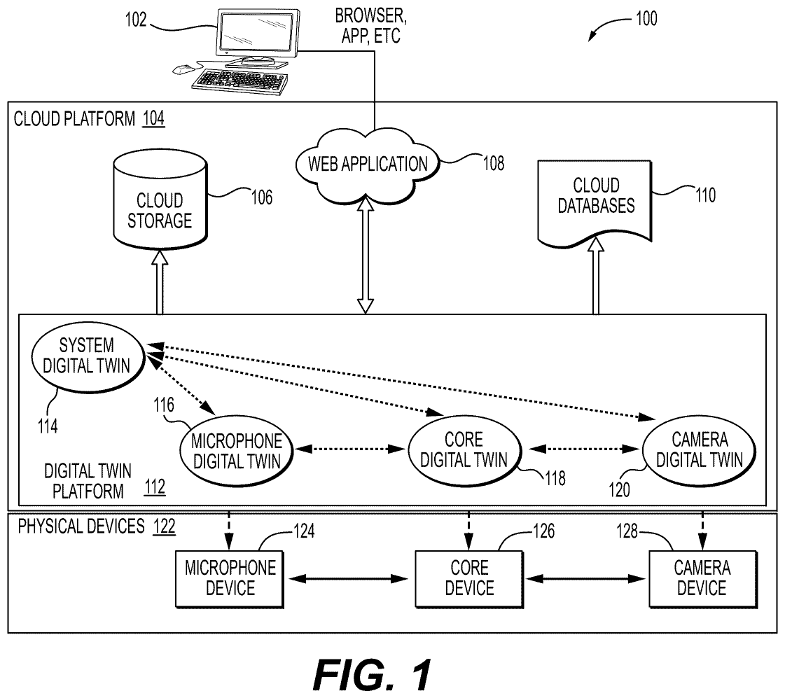

FIG. 1 illustrates an example cloud-based AVC system 100, according to embodiments of the present disclosure. In some embodiments, the cloud-based AVC system 100 may include a computing device 102 (e.g., a laptop, smart device, smart phone, tablet, personal computer, and the like), a cloud platform 104, a digital twin platform 112 as part of the cloud platform 104, and a set of physical devices 122.

In some embodiments, the physical devices 122 may include, one or more of, video cameras (e.g., internet-protocol video cameras), microphones (e.g., dynamic beamforming microphones and static microphones), speakers, displays and monitors, touchscreen devices, bridging devices, amplifiers, processing cores, and/or any other devices—whether a native device or a third-party device that is compatible from, e.g., creation of a plugin that allows the third-party device to integrate with the AVC system. For example, in some embodiments, native devices may include a Q-SYS® product, manufactured and provided by QSC, LLC, of Costa Mesa, Calif. In this regard, by creating the AVC setup, the design engineer may identify the devices that are to be included in the AVC system.

In some embodiments, the AVC system 100 may include the physical devices 122, digital twins, and virtual devices. Virtual devices in this AVC system 100 may mirror physical devices or may operate as independent, standalone virtual components. A physical device may be an edge device, for example, a physical entity that performs actions, runs software, and manipulates or transforms data. A virtual device may be an entity that runs the same, or substantially similar, software as the virtual device, manipulates and transforms data in exactly the same way, or in a substantially similar way, as a comparable physical device. The virtual device, however, may be present in the cloud. A virtual device may be able to perform any processing that a corresponding physical could otherwise do. In some embodiments, a virtual device may completely emulate their physical device counterparts. Together, these elements can create a dynamic, flexible AVC setup that can be carefully designed, tested, and tuned within a cloud platform, then deploy the design to a physical AVC system.

In some embodiments, the AVC system 100 may include at least two types of virtual devices: a virtual mirror and a standalone virtual device. A virtual mirror is a virtual version that accurately represents a corresponding physical device in the AVC system. A standalone virtual device may be a unique virtual component, without a physical counterpart, designed to perform specific functions within the AVC system.

A virtual device may have various functional capabilities. For example, a virtual device may be able to process emulated AVC inputs, which could be either live signals or recorded data. A virtual device may allow monitoring of their outputs in real-time or record them for future analysis and review.

In some embodiments, the cloud platform 104 may be a large, multiservice offering that can host various compute resources, other platforms as a service (e.g., digital twin platform 112), and distributed, scalable software offerings—such as a web application 108. In some embodiments, the cloud platform 104 may include any one of a cloud storage 106, the web application 108, and one or more cloud databases 110. Any one of the components within the cloud platform 104, including the cloud storage 106, the cloud databases 110, and the digital twin platform 112 may be co-located (e.g., within the same server in the same data center) or located remotely from each other (e.g., spanning multiple servers within a single data center or across multiple data centers).

Cloud platform 104 may be a cloud native application. For example, a user may interact with cloud platform 104 through a cloud interface (e.g., the web application 108) via the computing device 102.

The digital twin platform 112 may be a platform as a service that enables the creation, storage, relationship management, and data management of digital twins. In some embodiments, the digital twin platform 112 may include one or more of a system digital twin 114, a microphone digital twin 116, a core digital twin 118, and a camera digital twin 120. In some embodiments, twin-to-twin relationships may exist between the digital twins 114-120 (as shown by the dotted lines in FIGS. 1-4). In some examples, there may be a digital twin of each physical device of a physical AVC setup and a digital twin of the collective AVC system.

Each of the digital twins (e.g., the microphone digital twin 116, the core digital twin 118, and the camera digital twin 120 may have a counterpart physical device (e.g., a microphone device 124, a core device 126, and a camera device 128) within the set of physical devices 122. One or more of the physical devices 122 may be, for example, an edge device.

Each of the physical devices 122 may be a physical entity that performs actions, runs software, and manipulates or transforms data. Examples of physical devices may include, but are not limited to, video cameras (e.g., internet-protocol video cameras), microphones (e.g., dynamic beamforming microphones and stationary microphones), speakers, displays and monitors, touchscreen devices, bridging devices (e.g., AV bridging devices), amplifiers, processing cores, and/or any other devices—whether a native device or a third-party device that is compatible, e.g., creation of a plugin that allows the third-party device to integrate with an existing computing system.

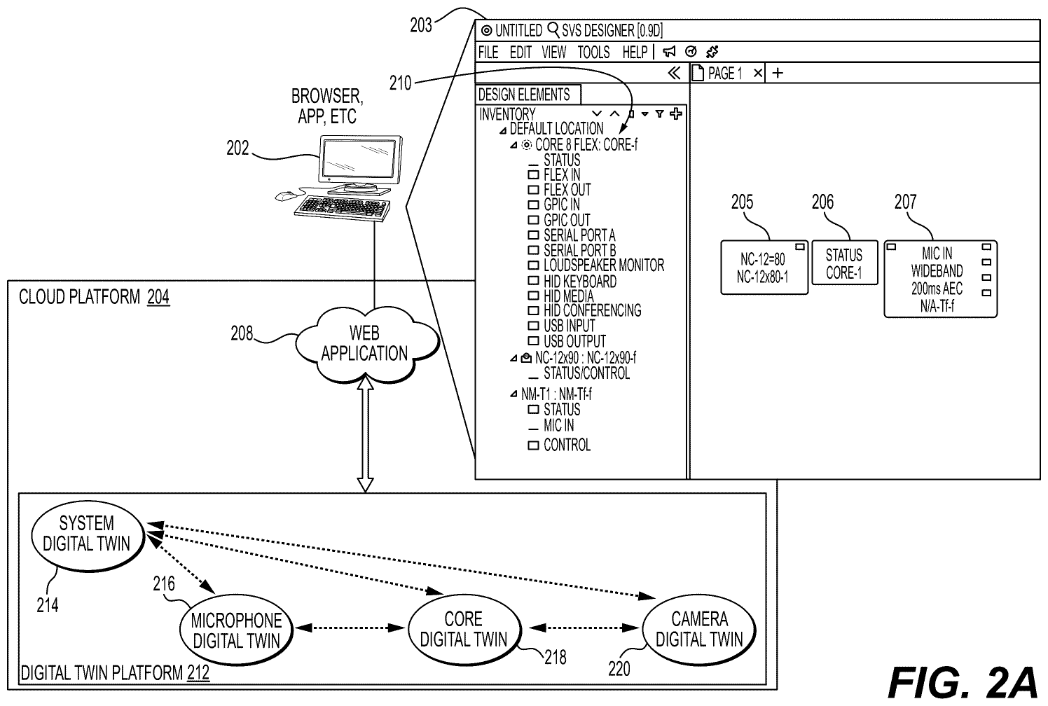

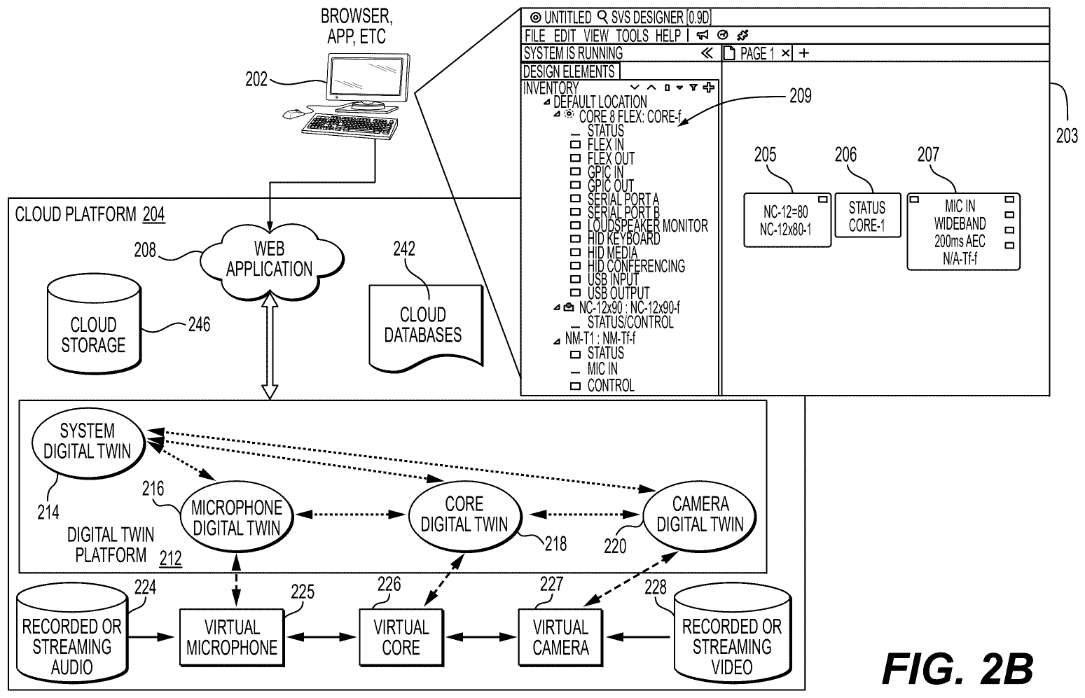

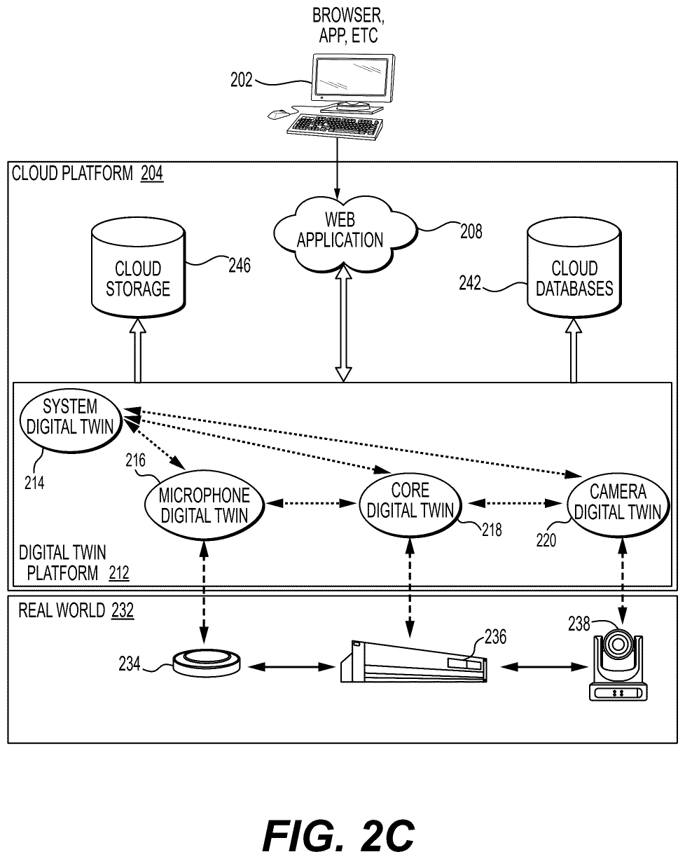

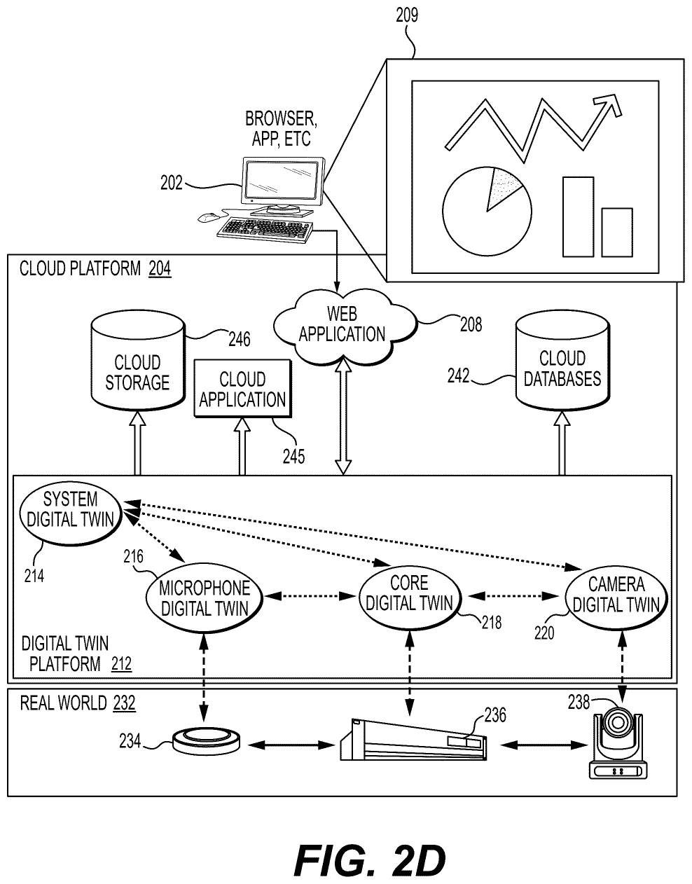

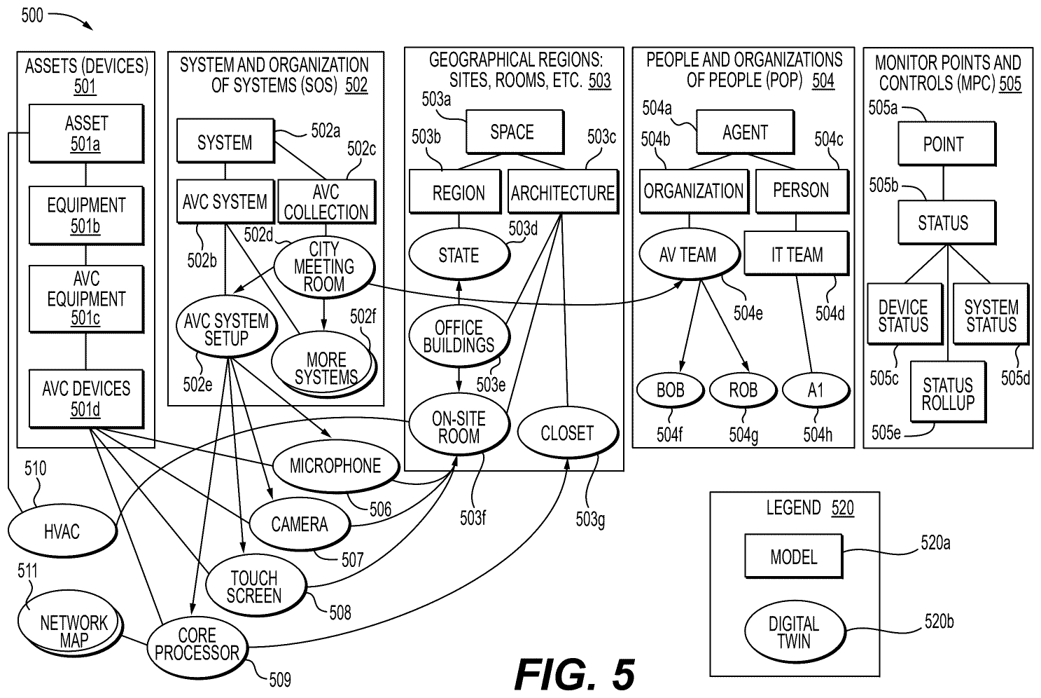

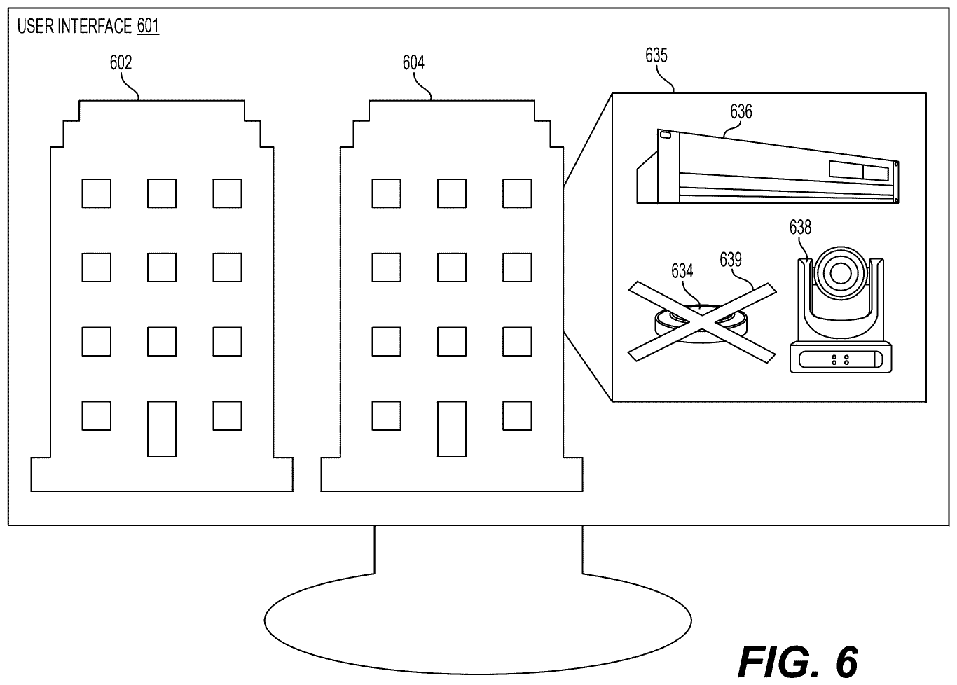

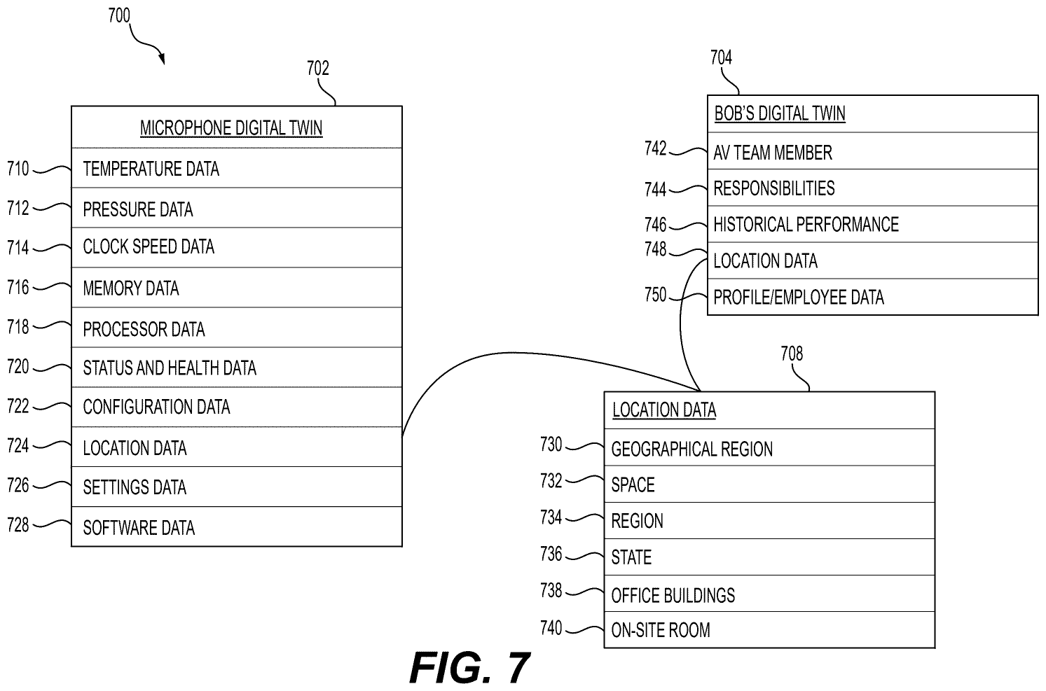

Each digital twin 116-120 may be configured to include, and capture in real-time, settings, controls, telemetry data, and so on of their counterpart physical device 124-128. The digital twins 116-120 may capture characteristics, behaviors, and functionalities of the physical devices 124-128, enabling real-time monitoring, analysis, and optimization. Data captured by digital twins 116-120 may be stored within cloud databases 110 (e.g., cloud databases 242, as discussed with reference to at least FIGS. 2B-2D and 5). Further, the data may be structured for quick retrieval, for example, for creating an ontological graph, as discussed with reference to FIGS. 5-7.

In some embodiments, for example, the digital twins 116-120 may mirror the state of their counterpart physical device 124-128, as well as the state of the AVC system. For example, if the microphone device 124 is activated, the microphone digital twin 116 may reflect the activated status of the microphone device 124. As another example, if camera device 128 were to receive instructions from core device 126 to change pan-tilt-zoom (PTZ) coordinates, the camera digital twin 120 may reflect those received instructions.

In addition, technical aspects of the present disclosure provide for digital twins 114-120 to integrate with digital twins of other systems, for example, those representing an HVAC system, a lighting system, a fire alarm system, a security system, and so on within, for example, a conference room, a building, or any structure.

Inter-device communication between physical devices 124-128 may be required to operate, control, configure, and otherwise pass data between two devices. For example, each physical device 124-128 may communicate with any other physical device 124-128 to carry out tasks (as shown by solid arrow lines in FIGS. 1-4), such as transmit streaming audio data captured within a surrounding environment from the microphone device 124 to the core device 126, send PTZ movement commands from the core device 126 to the camera device 128, and so on.

Further, technical aspects of the present disclosure provide communication between a physical device 124-128 and their counterpart digital twin 116-120 (as shown by dashed arrows in FIGS. 1-4). The communication between a physical device and its counterpart digital twin may include synchronization of telemetry, parameters, settings, and events between the physical device and its digital twin. For example, the microphone device 124 may communicate with the microphone digital twin 116 to synchronize telemetry data (e.g., captured audio data, any processing of such data that occurs within the microphone device 124, and/or any other type of data), settings, events, and so on. The core device 126 may communicate with the core digital twin 118 to synchronize telemetry data (e.g., processed audio data and video data, etc.), settings, events and so on. The camera device 128 may communicate with the camera digital twin 120 to synchronize telemetry data (e.g., captured video data, tracked objects within a field of view, etc.), settings (e.g., PTZ coordinates, etc.), events and so on. Likewise, if there is an adjustment to any digital twin 116-120, the adjusted digital twin(s) 116-120 may reflect that adjustment down to the respective device(s) 124-128.

In some embodiments, each of the physical devices 124-128 may continuously transmit real-time data about their status, operations, and conditions to their counterpart digital twin 116-120. This continuous transmission of real-time data may ensure that the digital twins 116-120 has an up-to-date representation of the state and configuration of each counterpart device 124-128.

Currently, setup of a conventional AVC system requires design and installation by experienced AV professionals who ensure correct functioning of an AVC setup. This can be a laborious and time-consuming process for the professional and financially demanding for the customer who purchased the AVC system. Typically, the professional would need to be in-person at the site of the AVC setup and use a computing device to download design software for creating a schematic of the AVC setup. Once the schematic is complete, in-person testing is required so that the professional can work out any sound processing, video processing, and/or control processing issues.

Technical aspects of the present disclosure provide for use of digital twins for remote configuration and setup of a physical AVC system. Specifically, changes made to the configuration or settings of the digital twins via the web application may be deployed to a corresponding physical device, allowing for remote setup and adjustments of an AVC system. The digital twins 114-120 may be used to conceptualize a new AVC setup or modification.

FIGS. 2A-D are diagrams illustrating steps of an AVC setup process using digital twins. In some embodiments, the AVC setup process may include three steps: design, emulate, and deploy. FIG. 2A is a diagram illustrating an example of the design step of the AVC setup process. In some embodiments, a web application 208 may accept a design for an AVC setup via a computing device 202. For example, a user interface 203 of the computing device 202 may display the web application 208 that a user may interact with to design the AVC setup.

The web application 208 may allow a user to design a schematic for an AVC setup by presenting different inventory items and components 210 relating to an AVC system. In some embodiments, the items and components may include a camera element 205, a core processor element 206, and a microphone element 207. Further, the web application 208 may receive a selection for specifications and settings for each element 205-207 presented within the user interface 203. For example, specifications and settings for each element 205-207 may include any one or more of gain and level adjustments, echo removal, echo reduction, mixing, encoding/decoding, color or resolution adjustments, cropping, delay control, input control, and/or process and logic control, and so on, for at least one of the elements 205-207.

In some embodiments, when the design for the AVC setup is complete, the digital twin platform 212 may instantiate a digital twin corresponding to each element 205-207. For example, in some embodiments, there may be a microphone digital twin 216 corresponding to the microphone element 207, a core digital twin 218 corresponding to the core processor element 206, a camera digital twin 220 corresponding to the camera element 205, and a system digital twin 214 corresponding to the AVC system created or represented by the camera element 205, the core processor element 206, and the microphone element 207. The system digital twin 214, the microphone digital twin 216, the core digital twin 218, and the camera digital twin 220 may become a ‘ground truth’ of an AVC system and may represent a current state of the corresponding physical devices (e.g., physical devices 124, 126, and 128) once the physical device are configured. Further, the digital twins 114-120 may be the objects that are acted upon when the AVC system is controlled. The digital twins 114-120 may then synchronize their settings with the physical devices 124-128.

In some embodiments, the AVC design may be first configured externally to the cloud platform 204 and then later linked to the cloud platform 204. In other embodiments, the AVC design may be create within the cloud platform 204. For example, in some embodiments, a user may create the AVC design on the computing device 202 (e.g., in a Window's based operating system) and then push that design to the core device 126. The core device 126 may send ontological data to the cloud platform 204. The user can select which peripherals are part of the design and the core device 126 can instantiate a digital twin of each of the peripherals and synchronize the digital twin to the peripherals. The core device 126 may act to transmit the ontological data required to synchronize the digital twin.

In some embodiments, a user may create the AVC design within the cloud platform 204 and one or more digital twins may be automatically instantiated based on the design. The cloud platform may deploy the AVC design to the core device 126. The digital twins may be automatically synched with each peripheral and the core of the AVC system set-up. For each of the two workflows (i.e., AVC design created external to the cloud platform and AVC design created within the cloud platform), a user may enter information relating to the physical aspects of the environment where the equipment is located.

FIG. 2B illustrates one or more virtual devices within the cloud platform 204 emulating a physical AVC system, prior to deploying a design to the AVC setup. For example, virtual devices may emulate physical devices by replicating their hardware behavior and characteristics using software.

In some embodiments, emulation may begin with the web application 208 receiving instructions to emulate the designed AVC setup (e.g., each of the elements 205-207 shown within user interface 203); the instructions being input, e.g., by a user, to computing device 202. After receiving the instructions to emulate a design, the cloud platform 204 may instantiate at least one virtual device based on each of the camera element 205, the core processor element 206, and the microphone element 207, selected within the design displayed within the user interface 203.

Each virtual device 225-227 may be instantiated according to the telemetry data, state, parameters, settings, and so on of their corresponding digital twin 216-220. During emulation and at other times (e.g., testing a firmware update), each virtual device 225-227 may interact with its corresponding digital twin 216-220. This way, virtual devices 225-227 mirror physical devices 126-128. Each virtual device 225-227 may emulate processing and operation of a corresponding physical device (e.g., physical devices 124-128) to predict real-world behavior and operation of the individual physical device and as part of an AVC system. Virtual devices 225-227 may run the same software/code/firmware/configurations as their physical device counterparts 124-128, thereby allowing for flexibility, testing, and isolation by mimicking hardware and/or software of physical devices 124-128.

To validate or verify that a designed AVC setup will work properly, the web application 208 may receive instructions, via the computing device 202, to emulate the signals or signal types (e.g., audio signals, video signals, and/or control signals) that physical devices 124-128 would receive during real-world operation. For example, real-world audio sources and video signals can be replaced by recorded audio sources or streaming audio sources, that are stored within a recorded or streaming audio database 224. Likewise, real-world video sources and video signals can be replaced by recorded video sources or streaming video sources, that are stored within a recorded or streaming video database 228. Each of the recorded and streaming audio and video databases 224, 228 may be stored in cloud storage.

During emulation, the virtual devices 225-227 may process the recorded audio sources or streaming audio sources and the recorded video sources or streaming video sources. For example, the virtual core 226 may process the recorded audio sources or streaming audio sources received from the virtual microphone 225. The processing of the recorded or streaming audio sources may be according to the specification and settings, as discussed above with reference to FIG. 2A. For example, the virtual core 226 may employ gain and level adjustments, echo removal, echo reduction, mixing, delay control, input control, and/or process and logic control, and so on to the recorded audio sources or streaming audio sources received from the virtual microphone 225. As another example, the virtual core 226 may employ encoding/decoding, color or resolution adjustments, cropping, delay control, input control, and/or process and logic control, and so on to the recorded video sources or streaming video sources received from the virtual camera 227.

According to technical aspects of the disclosure, in some embodiments, the cloud platform 204 may further include a verifier module (not shown) that verifies, within a threshold, that the virtual devices 225-227 are properly processing the recorded and streaming audio and video sources. Alternatively, web application 208 may present output from the virtual devices 225-227 via computing device 202, and may receive user input indicating the user is satisfied with how the virtual devices 225-227 have processed the recorded and streaming audio and video sources.

FIG. 2C is a diagram illustrating deployment of the settings and configurations from the cloud platform 204 to an AVC system including one or more physical devices in the real world 232. In some embodiments, the physical devices may include, but not be limited to, a physical microphone 234, a physical core 236, and a physical camera 238, which may be the same or substantially similar to the physical devices 124-128. When the virtual devices (e.g., virtual devices 225-227) have properly processed recorded and streaming audio and video sources during emulation, the cloud platform 204 may deploy the design to the physical devices 234-238. For example, the same or substantially the same configuration, settings, parameters, states, software, firmware, signal routing, and so on that was present in the virtual devices during emulation may be transferred to physical devices 234-238 via the digital twins 216-220.

For example, the physical microphone 234 may receive the configuration, settings, parameters, states, software, signal routing, and so on that was present in virtual microphone 225. Likewise, the physical core 236 and the physical camera 238 may receive the same configuration, settings, parameters, states, software, signal routing, and so on that was present in the virtual core 226 and the virtual camera 227, respectively.

The physical core 236 may process audio signals received from, and captured by, the physical microphone 234 using the same gain and level adjustments, echo removal, echo reduction, mixing, delay control, input control, and/or process and logic control, and so on that the virtual core 226 used to process the recorded audio sources or streaming audio sources received from virtual microphone 225. Likewise, the physical core 236 may process video signals received from, and captured by, the physical camera 238 using the same encoding/decoding, color or resolution adjustments, cropping, delay control, input control, and/or process and logic control, and so on that virtual core 226 used to process the recorded video sources or streaming video sources received from virtual camera 227.

In some embodiments, after the settings and configurations have been deployed from cloud platform 204 to physical devices 234-238, the cloud platform 204 may monitor behavior, health, performance, status, and so on of physical devices 234-238. FIG. 2D illustrates the cloud platform 204 monitoring the behavior of a physical device via their counterpart digital twin, and recording the monitored behavior for analysis and review.

In some embodiments, the digital twin platform 212 may store information (e.g., settings, status, health, configuration, parameters, behavior, and so on, as discussed throughout) stored within the digital twins 214-220 within the cloud databases 242. A cloud application 245, such as an artificial intelligence application, may retrieve and then process the information stored in the cloud databases 242 to identify trends and patterns, potential issues, and/or failures before they occur, enabling proactive maintenance and minimizing downtime. In one example, once the cloud application 245 identifies a potential issue or failure, the cloud application 245 may determine a potential solution. The cloud platform 204 may remedy the potential issue or failure by testing the veracity of the solution, for example, by emulating proposed changes to virtual devices 225-227 before propagating to the physical devices 234-238.

In some embodiments, the web application 208 may retrieve the information stored within cloud databases 242 and format the retrieved information for presentation within a user interface 209. For example, web application 208 may format the retrieved information (e.g., raw data) to include charts, identified trends, metrics, historical data, potential issues, and the like. Further, web application 208 may provide functionality so that a user may manipulate the retrieved information in a format that the user desires. For example, web application 208, via computing device 202, may receive a request to display errors occurring for physical device 234 from a time range over the past four months. Responsive to this request, web application 208 may retrieve information in a format that presents a bar chart of each error occurring over the past four months for display within the user interface 209.

In some embodiments, the web application 208 may prompt alerts when a physical device 234-238 requires attention (e.g., physical microphone device 234 needs replacement or a software upgrade is required). The alert may be sent to a user device (e.g., computing device 202) in the form of an audial or visual signal, for example, for presentation within the user interface 209 and/or an associated sound. The web application 208 may include a feature for receiving instant feedback from a user (e.g., IT or AV professional), for example, to upgrade the software of physical device 234-238 after at least one counterpart virtual device 225-227 has emulated the software upgrade. As another example, absent an alert, the web application 208 may receive a request to adjust settings or configurations of any one of physical devices 234-238, such as upgrade the software of a device. The digital twin platform 212 may then make the adjustment to the counterpart digital twin 214-220 or virtual device 225-227 before propagating the adjustment to the physical device 234-238.

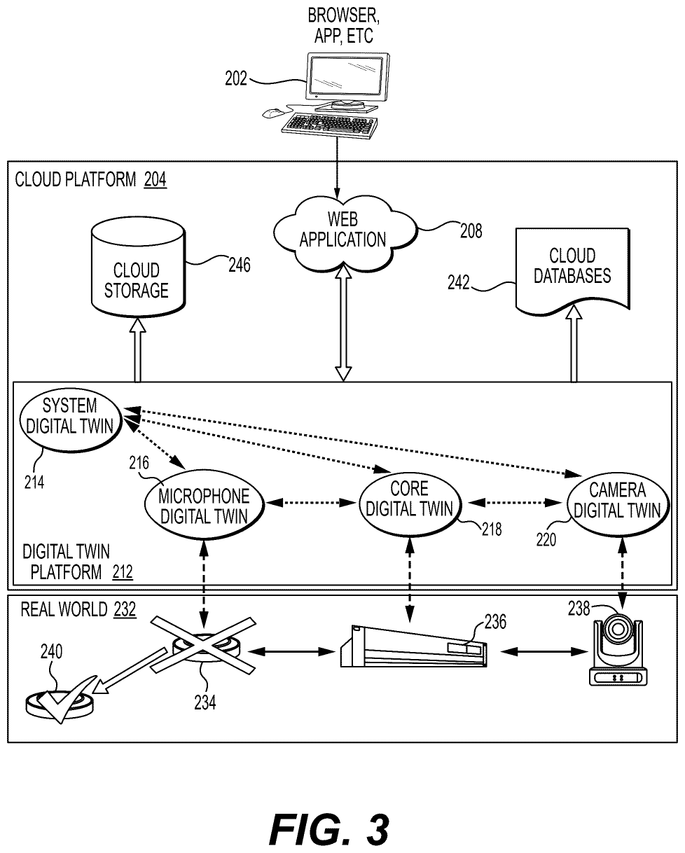

FIG. 3 illustrates a digital twin updating a physical, replacement device with settings, parameters, configuration data, and so on stored in the digital twin. As discussed above, each digital twin 216-218 may be continuously synchronized to their real-world, physical counterpart device 234-238. Therefore, the digital twin 234-238 may be a mirror of their counterpart physical device, in that the digital twin 234-238 may be synchronized with their respective, counterpart physical device by storing and/or collecting any one or more of the following, non-exhaustive list: operational, real-time data (e.g., temperature data, pressure data, clock speed data, memory and processor allocation, hardware information, or any other parameter data); historical data (e.g., past data on the performance and status of the physical device); spatial data (e.g., data related to location and physical arrangement of the physical device, such as within a building); configuration data (e.g., data relating to setup, settings, and current configuration of the physical device, including gain and level adjustments, echo removal, echo reduction, mixing, encoding/decoding, color or resolution adjustments, cropping, delay control, input control, and/or process and logic control); maintenance and health records (e.g., information relating to past maintenance activities, software and firmware updates, faults, repairs, battery performance, and the overall health of the physical device); external and environmental data (e.g., information relating to the environment surrounding the physical device, such as ambient temperature); performance metrics (e.g., data collected on the physical device meeting objectives); lifecycle data (e.g., data relating to a current phase of the physical device's lifecycle, including design, production, operation, or decommissioning); sensory data (e.g., data captured by the physical device, including audio data captured by physical microphone 234, video data captured by physical camera 238, and so on); software/firmware versions (e.g., software or firmware currently installed on the physical device; connectivity and network data (e.g., network connection data, including status, uptime, and potential network issues); operational guidelines and constraints (e.g., data on the limits within which the physical device should operate to ensure efficiency); and so on.

When, for example, the physical device 234 requires replacement (e.g., it is broken or running inefficiently), the physical device 234 may be replaced with a replacement physical device 240 by connecting the replacement physical device 240 to the existing AVC system. The digital twin 216 may update the replacement physical device 240 with settings, firmware, configuration, routing, and any other information, that is stored within the digital twin 216, and required to properly update the replacement physical device 240 with the settings, firmware, configuration, routing, and so on of physical device 234.

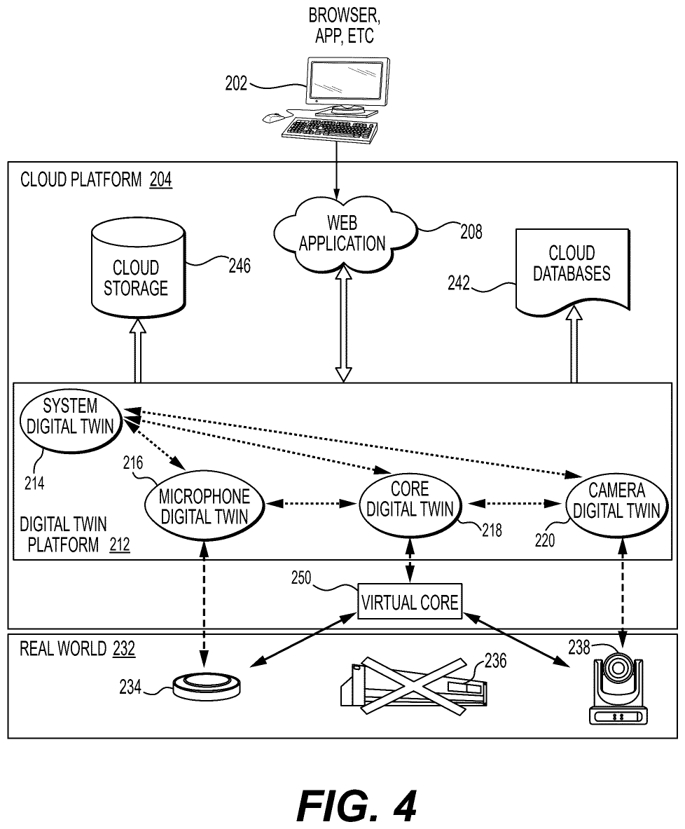

Technical aspects of this disclosure further support processing of audio, video, and control signals to be performed completely, or near completely, by a virtual processing core in the cloud platform. FIG. 4 illustrates a virtual core 250 capable of processing audio signals, video signals, and control signals captured by the microphone device 234, the camera device 238, or transmitted by a control device (e.g., a touch-screen device; not shown in FIG. 4), respectively. For example, the virtual core 250 may perform gain and level adjustments, echo removal, echo reduction, mixing, encoding/decoding, color or resolution adjustments, cropping, delay control, input control, and/or process and logic control to received audio and video signals. Further, the virtual core 250 may send command and control instructions, for example, received from a touch-screen device (not shown) to either one of microphone device 234 or camera device 238.

When the physical core 236 undergoes performance degradation, rather than replacing physical core 236 with another physical core, the cloud platform 204 may instantiate virtual core 250 and the core digital twin 218 may update virtual core 250 with configuration, software, firmware, settings, and other data stored within core digital twin 218. Therefore, there may not be any need for a physical replacement, for example, when time does not permit replacing the physical core 236 with a replacement physical core.

Typically, the physical devices of an AVC system involve advanced, real-time processing, high bandwidth and networking harmony (e.g., to sync audio signals with video signals), and minimal latency; all of which may demand processing of audio signals, video signals, and control signals to occur at the edge of the network, rather than in, for example, cloud platform 204 or to a centralized data center. In some embodiments, the physical core 236 may include an operating system that can manage routing of which audio signals, video signals, and control signals are processed at physical core 236 and which of the signals are processed within cloud platform 204. For example, the operating system may be an AVC operating system, a guest operating system established within a host AVC operating system, or a host operating system that has established a guest AVC operating system within. In the following examples of routing signals to the cloud platform 204 for processing, either the operating system and/or AVC operating system may make the determination of routing the signals at the physical core 236 or at the cloud platform 204. Further, in some embodiments, each physical device 234-238 may be an IoT device connected over a network to cloud platform 204.

In some embodiments, when latency of routing signals between cloud platform 204 and real world 232 is acceptably low, certain processing tasks may be partially or fully transferred to cloud platform 204. For example, predetermined types of signals that can be routed to and processed within the cloud platform 204 by the virtual core 250, such as control signals, within a threshold (e.g., fewer than 100 milliseconds or another timeframe), may be routed to and processed by the virtual core 250. For example, system settings may require that audio signals and video signals are processed by the physical core 236, whereas control signals may be routed to and processed by the virtual core 250.

Likewise, there may be a determination that latency of routing signals between the cloud platform 204 and the real world 232 is unacceptably high. In this case, signals that were previously destined for processing by the virtual core 250 may be directed to the physical core 236 for processing at the edge.

In some embodiments, the AVC system settings may allow for manual adjustment of which types of signals are processed by either of the physical core 236 or the virtual core 250. For example, the AVC system may be set, for example, within the web application 208, so that audio signals and control signals are routed to the cloud platform 204 for processing by the virtual core 250, whereas video signals are processed by the physical core 236.

In some embodiments, the virtual core 250 may share responsibilities of processing audio, video, and control signals with the physical core 236 based on a time the audio, video, or control signal spends in a queue. For example, in some embodiments, there may be a delay threshold where when any of audio signals, video signals, or control signals that have waited in a queue for over a predetermined amount of time, the signals in the queue that have remained for longer than the predetermined amount of time may be transmitted to the virtual core 250 for processing. In this case, the time required for transmitting to/from, and time to process by, the virtual core 250 may be considered when sending signals to virtual core 250 for processing.

In some embodiments, rather than sharing responsibilities based on a time a signal has spent in a queue, the signals may be routed to the virtual core 250 or the physical core 236 based on available computing resources (such as memory, computer processing units, graphical processing units, and the like) required to process the signal. If computing resources within either the physical core 236 or the virtual core 250 do not satisfy a computing resource threshold, indicating either the physical core 236 or the virtual core 250 has insufficient resources to complete processing of the signal, the signal may be routed to the other core, provided the other core has sufficient computing resources capable of completing the task.

In some embodiments, when the physical core 236 is unable to perform a task, for example, because the physical core 236 does not have the required software or hardware to perform the task, any one of audio signals, video signals, or control signals may be routed to the cloud platform 204 for completion of the task. For example, the cloud platform 204 may have software (e.g., application program interface) and/or hardware (e.g., central processing units, memory, and so on) required to complete one of the following: transcription, object detection, object recognition, among other examples, that physical core 236 is unable to complete. For example, the cloud platform 204 may instantiate a virtual device specifically for performing at least one task that is continuously running in the cloud platform 204 for, for example, a duration of a conference. The virtual device (not shown) may be a virtual artificial intelligence device capable of performing transcription, object detection, object recognition, and so on.

For example, the physical core 236 may route audio signals to the cloud platform 204 for a first cloud application (e.g., the virtual artificial intelligence device; not shown in FIG. 4) to perform transcription of audio signals captured by physical microphone 234. The transcription may be routed from the cloud platform 204 back to the physical core 236 for presentation within a physical display (not shown). For example, the physical core 236 may route video signals captured by the physical camera 238 to the cloud platform 204 for a second cloud application (e.g., the artificial intelligence device; not shown in FIG. 4) to perform object detection and/or perform object recognition by, for example, feeding the video signal to a neural network. The result of that may be routed from cloud platform 204 to physical core 236.

In some embodiments, one or more of the virtual devices 225-227 may exist within the cloud platform 204 as a standalone device or can be an extension of the digital twins 216-220 in the digital twin platform 212. For example, the virtual devices 225-27 can be incorporated within, or serve as, their respective digital twins 216-220 to further improve development and testing of the virtual devices 225-227, predictive maintenance, and real-time monitoring and control. For example, the microphone digital twin 216 may incorporate virtual microphone 225, the core digital twin 218 may incorporate the virtual core 226, and/or the camera digital twin 220 may incorporate the virtual camera 227.

In some embodiments, there may be a virtual switch (not shown) that provides a communication path to either one of a virtual device or a digital twin. For example, the virtual switch may provide a communication path between either one of the virtual core 226 or the core digital twin 218. In some embodiments, there may be no virtual switch, for example, when a digital twin has a virtual device embedded within, or incorporated into, the digital twin, there may be a direct communication path to the digital twin. For example, if the virtual core 226 is embedded within the core digital twin 218, there is a direct communication path to the core digital twin 218.

In some embodiments, to replicate and monitor the behavior of the physical devices (e.g., 124-128), the virtual devices 225-227 may serve as respective digital twins 216-220 of the respective physical devices 124-128. For example, the virtual microphone 225 may serve as the microphone digital twin 216, the virtual core 226 may serve as core digital twin 218, and the virtual camera 227 may serve as the camera digital twin 220. This way, the virtual devices 225-227 serving as respective digital twins 216-220 may capture, in real-time, settings, controls, telemetry data, and so on of the respective physical device 124-128 so that the virtual device 225-227 can emulate the behavior of the respective physical device 124-128 in real-time or near real-time.

Thus, the virtual devices 225-227 incorporated within, and in the form of, or serving as, digital twins 216-220 can provide real-time feedback, for example, for development and testing of software or firmware on a virtual device 225-227 before deploying the software or firmware on respective physical devices 124-128. Further, incorporating virtual devices 225-227 within digital twins 216-220 can provide predictive maintenance in that digital twins 216-220 can predict when respective physical devices 124-128 might fail. For example, by digital twins 216-220 incorporating and/or using virtual devices 225-227, potential solutions can be tested without risking integrity of respective physical devices 124-128. Further, the performance of one or more physical devices 124-128 can be monitored in real-time, that can be presented within web application. Further, the performance of physical devices 124-128 can be controlled in real-time in that adjustments made on digital twins 216-220 or virtual device 225-227 can be mirrored on respective physical devices 124-128.

In some embodiments, an ontology may enable creation of a knowledge graph or digital representation that maps relationships between physical devices (e.g., physical devices 124-128) and systems (e.g., an AVC system) to remotely organize, monitor, manage and control access to systems, and understand the relationship of a system, for example, that can be configured and presented within a web application (e.g., web application 208). An ontology may be described as a formal representation of a set of concepts within a specific domain and the relationships between those concepts. An ontology can be used to model a domain and can be used to understand, and draw relationships between, the entities within the domain.

In some embodiments, ontological data may be collected by digital twins 214-220 being synchronized to their respective physical devices 234-238, that can be used to create an ontological framework for manipulation and presentation by the web application 208. For example, in some embodiments, the web application 208 may provide (e.g., for presentation): a topological organization of one or more AVC systems (e.g., each AVC system may comprise one or more physical devices 234-238); grouping and classification of the one or more AVC systems; grouping and classification of an owner, administrator, and/or user of each of the one or more AVC systems; and/or access management to each of the one or more AVC systems. In addition, the ontology may represent each digital twin 214-220 of their respective physical device 234-238 in the real world 232, that includes settings, controls and indicators, and a representation of the design of each (e.g., as discussed with reference to FIG. 2A), components, properties and controls, and connectivity (e.g., wiring, networking, and so on) between them.

FIG. 5 is an example diagram illustrating an ontological graph 500 (knowledge graph) comprising a collection of ontological data in various classifications and relationships between such. The ontological data may be retrieved from the cloud databases 242 by the web application 208. As shown in FIG. 5, in some embodiments, there may be five classifications: assets 501, systems and organization of systems (SOS) 502, geographical regions 503, people and organizations of people (POP) 504, and monitor points and controls (MPC) 505. In other embodiments, there may be more or less than five classifications.

In the illustrated example, a legend 520 instructs that a rectangular shape denotes a ‘model,’ 520a and an ellipse shape denotes an instance of a digital twin 520b. For example, the classification, assets 501, may include models of physical equipment and/or physical devices, such as, for example, an Asset 501a, Equipment 501b (e.g., individual devices), AVC Equipment 501c, and AVC Device 501d (e.g., physical devices 124-128). Each model within the classification asset 501 may be a subtype of the model located above it. For example, AVC Device 501d may be a subtype of AVC Equipment 501c, AVC Equipment 501c may be a subtype of Equipment 501b, and Equipment 501b may be a subtype of Asset 501a. There may be more than one subtype for each type, as shown in the other classifications 502-505.

For example, in some embodiments, the classification, systems and organization of systems (SOS) 502, may include models for System 502a, AVC System 502b, and AVC Collection 502c, where AVC System 502b and AVC Collection 502c are both subtypes of System 502a. In some embodiments, for example, the classification, geographical regions 503, may include models for Space 503a, Region 503b, and Architecture 503c. In some embodiments, for example, the classification, people and organizations of people (POP) 504, may include models for Agent 504a, Organization 504b, Person 504c, and IT Team 504d. In some embodiments, for example, the classification, monitor points and controls (MPC) 505 may include models for Point 505a, Status 505b, Device Status 505c, System Status 505d, and Status Rollup 505e.

In some embodiments, there may be digital twins associated with the classifications. For example, in some embodiments, there may be digital twins of systems (e.g., City Meeting Room 502d, AVC System Setup 502e, More Systems 502f), of geographic regions (e.g., State 503d, Office Buildings 503e, On-Site Room 503f, and Closet 503g), of organizations (e.g., an AV Team 504e) and individual users (e.g., Bob, Rob, and Al).

In some embodiments, there may also be a digital twin of physical devices (e.g., microphone digital twin 506, camera digital twin 507, touch screen device digital twin 508, core processor digital twin 509, HVAC system digital twin 510, and so on) as discussed throughout the disclosure. Further, in some embodiments, there may be digital twins that are a subtype of a model, such as a Microphone digital twin being a subtype of AVC Devices model. In some embodiments, there may be a digital twin of the Network Map 511.

Links connecting digital twins to digital twins may represent a relationship between the two. For example, information stored within each of the Microphone, Camera, Touch Screen, and Core Processor digital twins may include the location of each respective physical device, for example, an on-site room within a specific office building located in a particular state. Thus, the links connecting each of the Microphone, Camera, Touch Screen, and Core Processor digital twins with the On-Site Room digital twin may be based on the location data stored in the physical devices' digital twins and the On-Site Room digital twin. Likewise, the State digital twin may include information stored that includes the AV Team that is designated to work on any AVC device (e.g., of which may be included within a smart infrastructure, discussed below) within the state. Hence, the link connecting the State digital twin with the AV Team digital twin may be based on the relationship between the two.

In some embodiments, digital twins (e.g., as discussed above and throughout the disclosure) can integrate with an existing digital twin platform. For example, referring to FIG. 5, the digital twins representing AVC devices 506-509 and AV Team 504e, may integrate with an existing digital twin platform. In some embodiments, digital twins and any information stored therein may integrate with an existing ontology, for example, a real-estate core. A real-estate core is an ontology that describes constituents of any type of real estate, such as a building, room, floor, ceiling, and so on, and/or any smart infrastructure (a smart HVAC system) or mechanical, electrical, or computing components thereof, such as a security system, fire alarm system, and so on.

For example, a corporation may own commercial real estate located in different geographic regions throughout the United States. The commercial real estate may include infrastructure, smart assets, and equipment, including a smart HVAC system within an on-site room, as shown in ontological graph 500. Further, there may already be an organization (i.e., an IT Team, Al) managing the smart infrastructure. An inclusion of AVC equipment and AVC devices, along with AVC System Setup (e.g., cloud platform, for AVC system design and management, as discussed throughout), and an AV Team, to the existing smart infrastructure within the commercial real estate may include integrating the digital twin platform of the AVC Equipment and AV Team to the existing smart infrastructure.

Referring to at least FIGS. 5-7, a cloud platform (e.g., cloud platform 204) may be capable of providing functionality (e.g., via web application 208) for creation of a world-view (e.g., as shown within user interface 601) based on an ontological graph 500. The world-view may be of, for example, geographical regions 503, that may include various sites (e.g., geographically remote from each other) that comprise office buildings (e.g., office buildings 602, 604), that comprise one or more levels (not shown in FIG. 5 or 6). Further, each level may comprise one or more on-site rooms that include physical devices (e.g., Microphones, Cameras, Touch Screens, Core Processors, and so on). In some embodiments, the world-view may be of any classification, for example, including assets 501, SOS 502, geographical regions 503, POP 504, and MPC 505.

User interface 601 (e.g., user interface 203) may present office buildings 602, 604, in the form of graphical representations of the Office Buildings' digital twins illustrated within ontological graph 500. For example, using the information stored within Office Buildings' digital twins, the cloud platform 204 or the web application 208 may construct the graphical representations for office buildings 602, 604, along with any other model or digital twin of ontological graph 500. For presentation of office buildings 602, 604 within user interface 601, a user (e.g., Bob from ontological graph 500) may instantiate the user's digital twin (e.g., Bob's digital twin 704 (e.g., digital twin 504f)) within web application 208 by, for example, inputting credentials to web application 208. Within ontological graph 500, a relationship may be identified between the information stored in Bob's digital twin 704 and physical devices' digital twins (e.g., microphone digital twin 702 (e.g., digital twin 506)), represented by a link between at least location data 708, that includes office buildings 602, 604, where on-site room 635 is located, and physical devices therein.

For example, in some embodiments, the microphone digital twin 702 may include a variety of data, such as but not limited to, temperature data 710, pressure data 712, clock speed data 714, memory data 716, processor data 718, status and health data 720, configuration data 722, location data 724, settings data 726, and software data 728. In some embodiments, the location data 708 may include information related to, but not limited to, geographical region 730, space 732, region 734, state 736, office buildings 738 (e.g., office building 602, 604), and on-site rooms 740. In some embodiments, Bob's digital twin 704 may include data/information related to, but not limited to, AV team member 742, responsibilities 744, historical performance 746, location data 748, and profile/employee data 750.

Web application 208 may present indicators (e.g., color indicators), within on-site room 635, based on information stored within on-site room's digital twin, that represent the status or health of a physical device. For example, in the illustrated example, office building 602 includes four levels, each having one or more on-site rooms (e.g., each on-site room 635 indicated by a representation of a square window on the building) that include at least one physical device. The square window representation of each on-site room may be colored based on the health or status of the room. For example, nine of the conference rooms may have the color green indicating a positive health and two of the conference rooms may have the color yellow indicates a semi-positive health. A semi-positive health may indicate that there is one or more physical devices 636-638 that have some type of performance degradation.

Further, office building 604 may include a single on-site room that is displayed in red indicating that there is at least one physical device 634 that is not working, that may have been determined from information stored within physical device's digital twin. For example, the user interface may present physical devices 634-638 that are running within on-site room 635 within office building 604. The user interface 601 may present physical device 634, for example, as not working by a ‘cross-out’ sign 639.

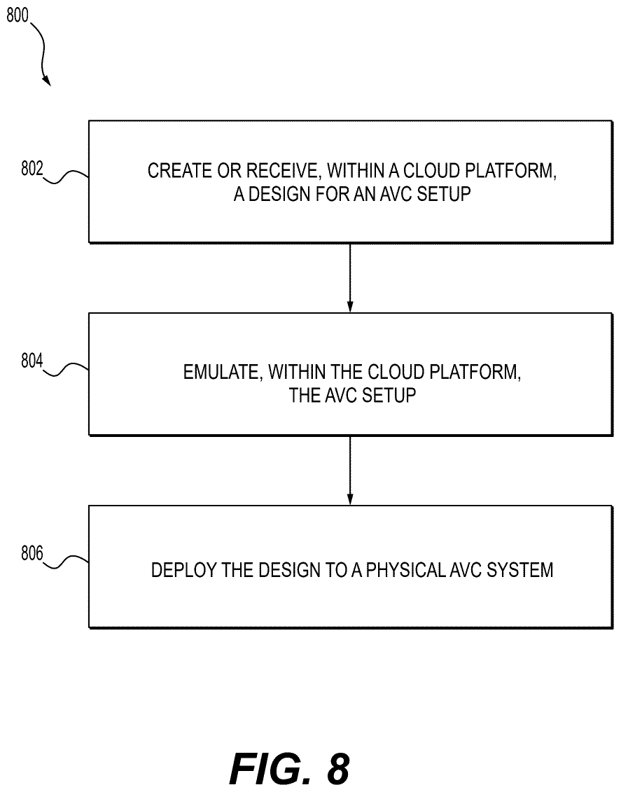

FIG. 8 is a flowchart illustrating an example method 800 for designing and emulating an AVC setup within a cloud platform, and then deploying the AVC setup from the cloud platform to at least one physical device. In some embodiments, method 800 may include receiving and/or creating, within a cloud platform, a design for an AVC setup 802, for example, as described with reference to FIG. 2A. The AVC setup may include a device configuration of the physical device that may include at least one of a setting, a parameter, a state, a software, a firmware, or a signal routing.

In some embodiments, method 800 may include emulating the AVC setup within the cloud platform 804, for example, as described with reference to FIG. 2B. For example, the method may include creating a digital twin of the physical device based on the device configuration, creating in the cloud platform a virtual device based on information stored in the digital twin of the physical device, and emulating, by the virtual device, signal processing and operation of the corresponding physical device to predict behavior and operation of the corresponding physical device. In some embodiments, method 800 may include deploying the design to a physical AVC system 806, for example, as described with reference to FIG. 2C.

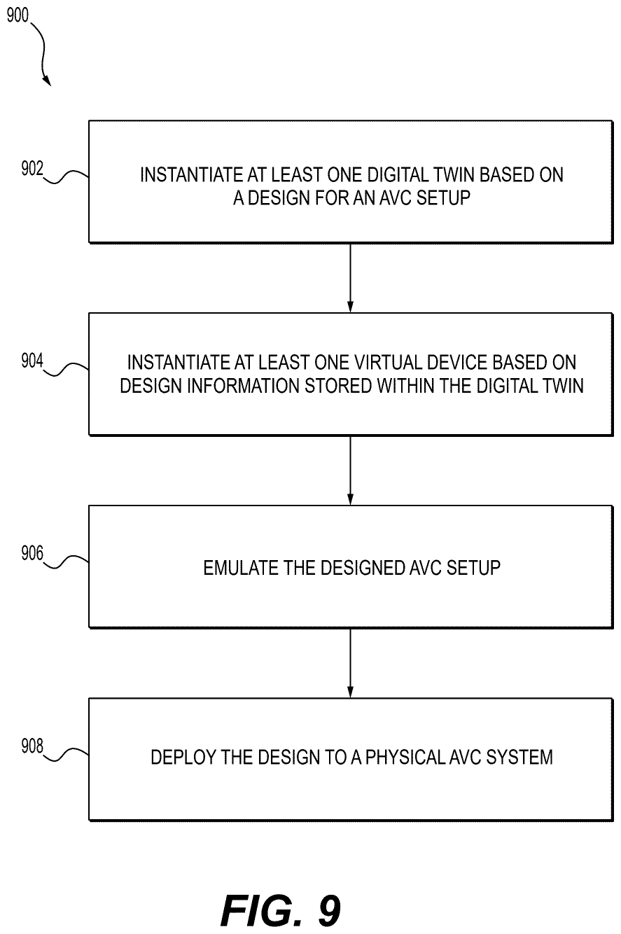

FIG. 9 is a flowchart illustrating an example method 900 for designing and emulating an AVC setup within a cloud platform, and then deploying the AVC setup from the cloud platform to at least one physical device. In some embodiments, method 900 may include instantiating at least one digital twin based on a design for an AVC setup 902. In some embodiments, method 900 may include instantiating at least one virtual device based on design information stored within the digital twin 904. In some embodiments, method 900 may include emulating the designed AVC setup 906. In some embodiments, method 900 may include deploying the design to a physical AVC system 908.

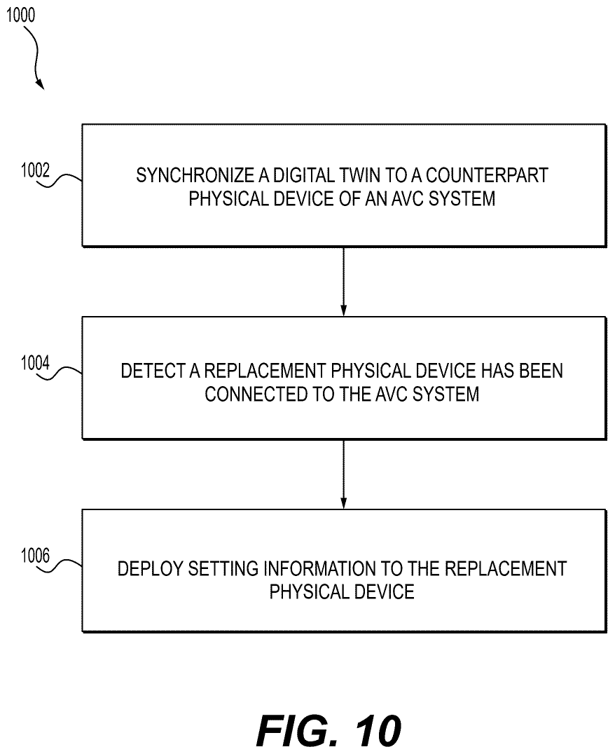

FIG. 10 is a flowchart illustrating an example method 1000 for transferring setting information from a digital twin to a replacement physical device. In some embodiments, method 1000 may include synchronizing a digital twin to a counterpart physical device of an AVC system 1002. In some embodiments, method 1000 may include detecting that a replacement physical device has been connected to the AVC system 1004. In some embodiments, method 1000 may include transferring setting information stored in the digital twin to the replacement physical device 1006. The transfer of information may be initiated by the physical device (i.e., the information is pulled from the digital twin) or may be initiated by the digital twin (i.e., the information is pushed from the digital twin to the physical device).

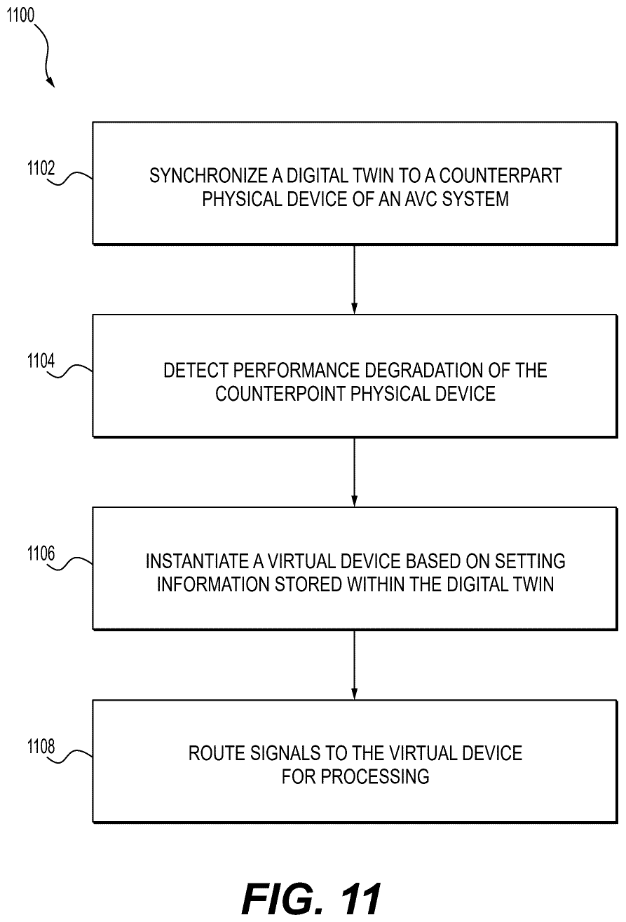

FIG. 11 is a flowchart illustrating an example method 1100 for redirecting signals to a virtual device upon detecting performance degradation of a physical device. In some embodiments, method 1100 may include synchronizing a digital twin with a counterpart physical device of an AVC system 1102. In some embodiments, method 1100 may include detecting performance degradation of the counterpart physical device 1104. In some embodiments, method 1100 may include instantiating a virtual device based on setting information stored within the digital twin 1106. In some embodiments, method 1100 may include routing signals to the virtual device for processing 1108.

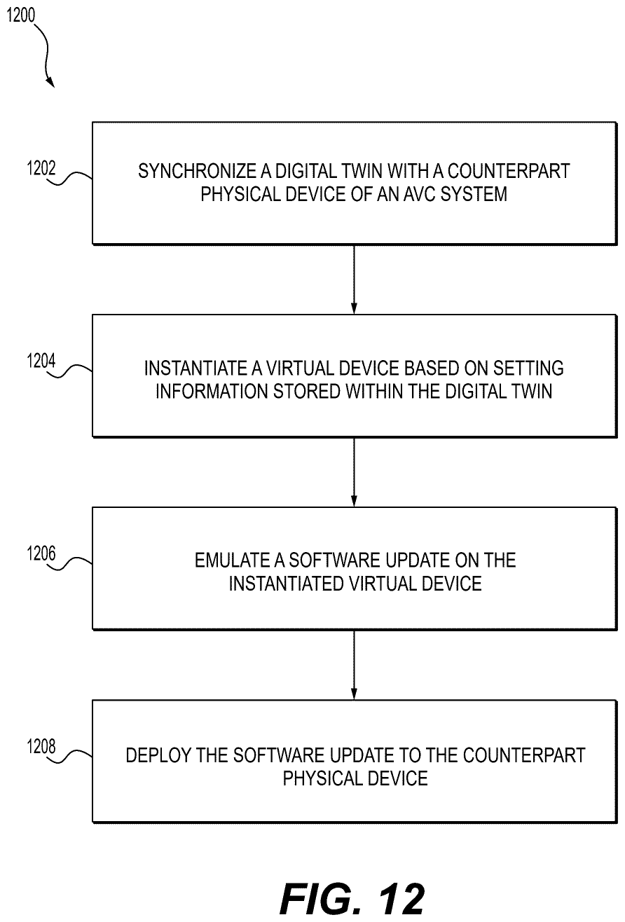

FIG. 12 is a flowchart illustrating an example method 1200 for emulating a software update on a virtual device prior to deploying the software update to a physical device. In some embodiments, method 1200 may include synchronizing a digital twin with a counterpart physical device of an AVC system 1202. In some embodiments, method 1200 may include instantiating a virtual device based on setting information stored within the digital twin 1204. In some embodiments, method 1200 may include emulating a software update on the instantiated virtual device 1206. In one example of block 1206, rather than emulating a software update, emulation may involve testing a virtual device for a security vulnerability. In some embodiments, method 1200 may include deploying the software update to the counterpart physical device 1208.

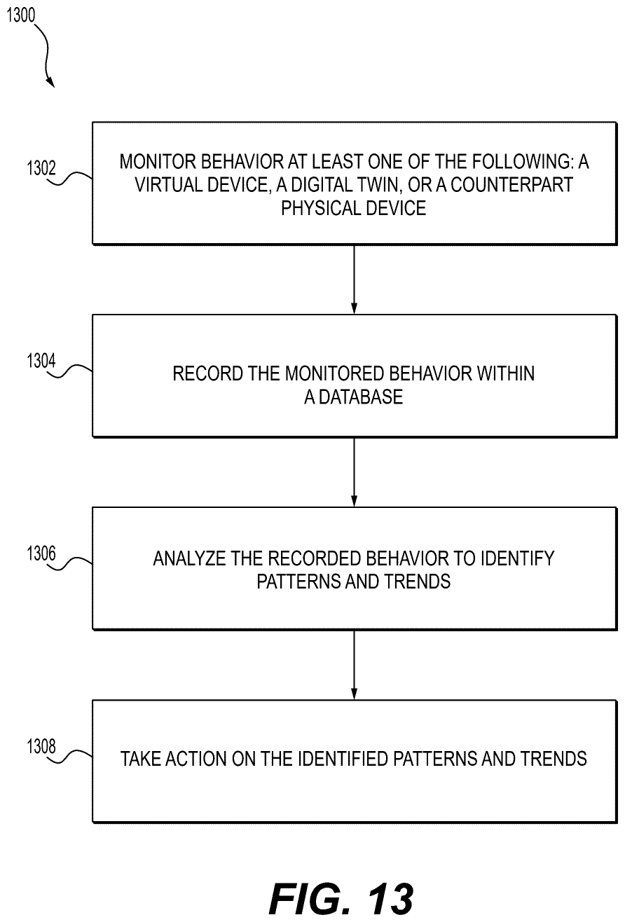

FIG. 13 is a flowchart illustrating an example method for monitoring behavior of a virtual system and recording such for analysis and review, according to embodiments of the present disclosure. In some embodiments, method 1300 may include monitoring behavior at least one of the following: a virtual device, a digital twin, or a counterpart physical device 1302. In one example of block 1302, monitoring the behavior may include monitoring outputs of each, for example, in real-time. In some embodiments, method 1300 may further include recording the monitored behavior within a database (e.g., cloud database 242) 1304.

In some embodiments, method 1300 may include analyzing the recorded behavior to identify patterns and trends 1306. In one example of block 1306, an application (e.g., an artificial intelligence application) within cloud platform 204 may retrieve recorded behavior from the database to identify potential issues or failures before they occur. In one example of block 1306, an identified potential issue may include a required software update of at least one physical device. In some embodiments, method 1300 may include acting on the identified patterns and trends 1308. In one example of block 1308, once a potential issue is identified, web application 208 may transmit an alert for presentation within user interface 209. In the example of identifying a required software update for at least one physical device, block 1308 may include emulating the software update on a virtual device before deploying to the counterpart physical device.

In one embodiment of method 1300, rather than performing blocks 1306 and 1308, the recorded, monitored behavior may be presented by web application 208 within user interface 209. The presentation of the recorded behavior may provide insights, trends and patterns, potential issues, and so on derived from the monitored behavior. For example, this embodiment may be substantially similar to as described with reference to FIG. 2D.

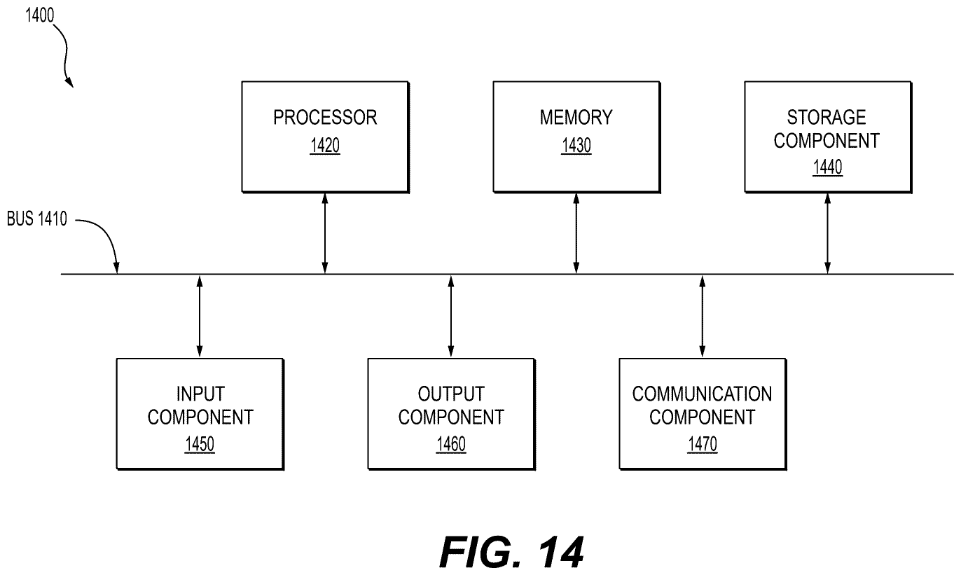

FIG. 14 is a diagram of example components of a device 1400, which may correspond to the devices described in embodiments of the present disclosure. In some implementations, the devices described throughout may include one or more devices 1400 and/or one or more components of the one or more devices 1400. As shown in FIG. 14, in some embodiments, the device 1400 may include one or more of a bus 1410, a processor 1420, a memory 1430, a storage component 1440, an input component 1450, an output component 1460, and a communication component 1470.

Bus 1410 may include a component that enables wired and/or wireless communication among the components of device 1400. Processor 1420 may include a central processing unit, a graphics processing unit, a microprocessor, a controller, a microcontroller, a digital signal processor, a field-programmable gate array, an application-specific integrated circuit, and/or another type of processing component. Processor 1420 may be implemented in hardware, firmware, or a combination of hardware and software. In some implementations, processor 1420 may include one or more processors capable of being programmed to perform a function. Memory 1430 may include a random-access memory, a read-only memory, and/or another type of memory (e.g., a flash memory, a magnetic memory, solid-state drive, and/or an optical memory).

Storage component 1440 may be configured to store information and/or software related to the operation of device 1400. For example, storage component 1440 may include a hard disk drive, a magnetic disk drive, an optical disk drive, a solid-state disk drive, a compact disc, a digital versatile disc, and/or another type of non-transitory computer-readable medium. Input component 1450 may be configured to enable device 1400 to receive input, such as user input and/or sensed inputs. For example, input component 1450 may include a touch screen, a keyboard, a keypad, a mouse, a button, a microphone, a switch, a sensor, a global positioning system component, an accelerometer, a gyroscope, and/or an actuator. Output component 1460 may be configured to enable device 1400 to provide output, such as via a display, a speaker, and/or one or more light-emitting diodes. Communication component 1470 may be configured to enable device 1400 to communicate with other devices, such as via a wired connection and/or a wireless connection. For example, communication component 1470 may include a receiver, a transmitter, a transceiver, a modem, a network interface card, and/or an antenna.

Device 1400 may perform one or more processes described herein. For example, a non-transitory computer-readable medium (e.g., memory 1430 and/or storage component 1440) may store a set of instructions (e.g., one or more instructions, code, software code, and/or program code) for execution by processor 1420. Processor 1420 may execute the set of instructions to perform one or more processes described herein. In some implementations, execution of the set of instructions, by one or more processors 1420, may cause one or more processors 1420 and/or device 1400 to perform one or more processes described herein. In some implementations, hardwired circuitry may be used instead of or in combination with the instructions to perform one or more processes described herein. Thus, implementations described herein are not limited to any specific combination of hardware circuitry and software.

The number and arrangement of components shown in FIG. 14 are provided as an example. Device 1400 may include additional components, fewer components, different components, or differently arranged components than those shown in FIG. 14. Additionally, or alternatively, a set of components (e.g., one or more components) of device 1400 may perform one or more functions described as being performed by another set of components of device 1400.

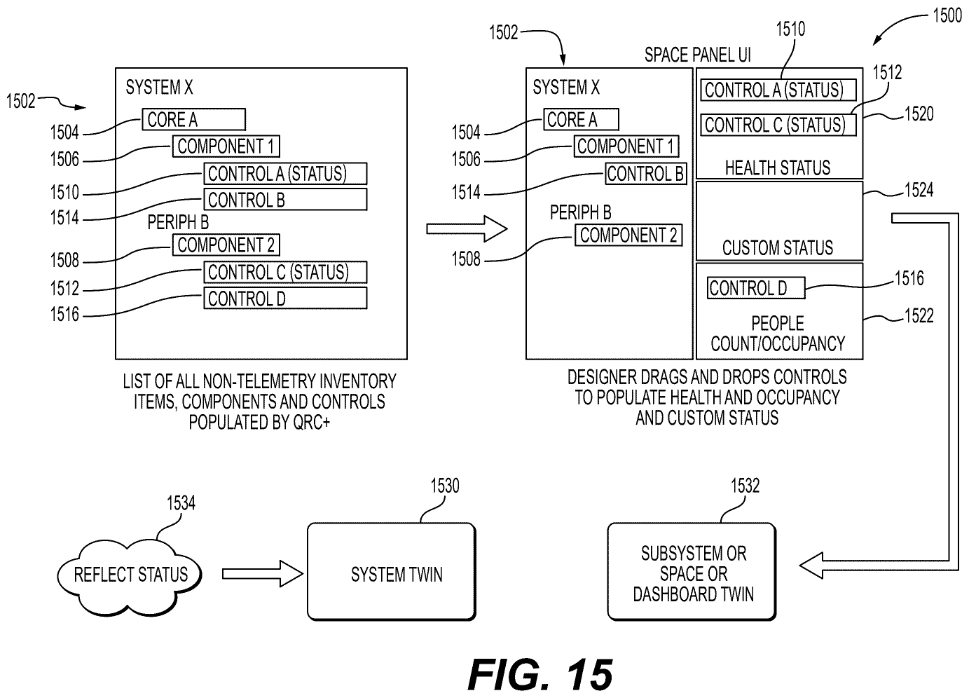

FIGS. 15-18 illustrate ontological representations for the AVC system and, in some examples, how the AVC may interact with another ontology. In some embodiments, the web application 208 (FIG. 2A) may allow a user to associate a system, and/or the inventory items in the system, and their statuses, to a particular space. In some embodiments, the web application 208 may include a user interface for each specific space (i.e., a space panel UI). For example, FIG. 15 illustrates an example space panel UI 1500 that includes a list panel 1502 for displaying a list of non-telemetry inventory items, components, and controls associated with the specific space. For example, an example space (e.g., a meeting room) may have a core processor, a first component or inventory item (e.g., a microphone) and a second component or inventory item (e.g., a camera) associated with the space. The list panel 1502 may include elements associated with the various non-telemetry inventory items, components, and controls in the space. For example, the list panel 1502 may include a core processor element 1504, a first component element 1506 (e.g., a microphone element), and second component element 1508 (e.g., a camera element) as inventory items or components.

The core processor, the first component, and the second component may have a status associated with the physical device that is indicative of the overall health (or an aspect of the overall health) of the physical device. The status of the core processor, the first component, and the second component may be represented as a control element in the list panel 1502. For example, in the illustrated example, the list panel 1502 may include a control a element 1510 representative of the status of the first component and a control c element 1512 representative of the status of the second component.

Further, one or more of the core processors, the first component, and the second component may have other controls associated with them that may be included on the list panel 1502, such as control b element 1514 associated with the first component and control d element 1516 associated with the second component. For example, the second component may be a camera that has the ability to identify the number of people within its field of view (i.e., people count). Thus, control d element 1516 in the list panel 1502 may represent a people count element associated with the camera.

In some embodiments, the web application may allow a user to define various aspects of the space by the controls of one or more of the physical devices in the space. In the example of FIG. 15, the system the space panel UI 1500 may include a status panel 1520, a people count panel 1522, and one or more additional panels (e.g., a custom panel 1524). To select one or more of the controls, in some embodiments, the user may move (e.g., drag and drop) or otherwise select, one or more of the control elements from the list panel 1502 to the status panel 1520, the people count panel 1522, and/or the one or more additional panels (e.g., the custom panel 1524). In this way, the user may define health status, people count/occupancy, or other controls of the space.

For example, if the user wants the health of the space to be represented by the combined health of the first component and the second component, the user may move, the control a element 1510 and the control c element 1512 from the list panel 1502 to the status panel 1520 (as indicated in FIG. 15 which shows control a element 1510 and the control c element 1512 in the status panel 1520 and no longer in the list panel 1502). Similarly, if the user wants the people count/occupancy of the space to be represented by the people count indicated by the people count functionality of the second component, the user may move the control element d 1516 from the list panel 1502 to the people count/occupancy panel 1522 (as indicated in FIG. 15 which shows control element d 1516 in the people count/occupancy panel 1522 and no longer in the list panel 1502). Thus, through the space panel UI, the Q-SYS system components and inventory items may be mapped or associated to physical spaces in the real estate world (e.g., to spaces in the real estate core).

Further, as discussed above regarding digital twins, the cloud entity may collect data associated with the controls (e.g. status data) from the AVC system and send the data to a system digital twin 1530 and the data related to the space (e.g., controls a-d) may be sent to a subsystem digital twin, a space digital twin, and/or a dashboard digital twin 1532. In some embodiments, the system digital twin 1530 may be reflective of the status of the cloud platform 1534.

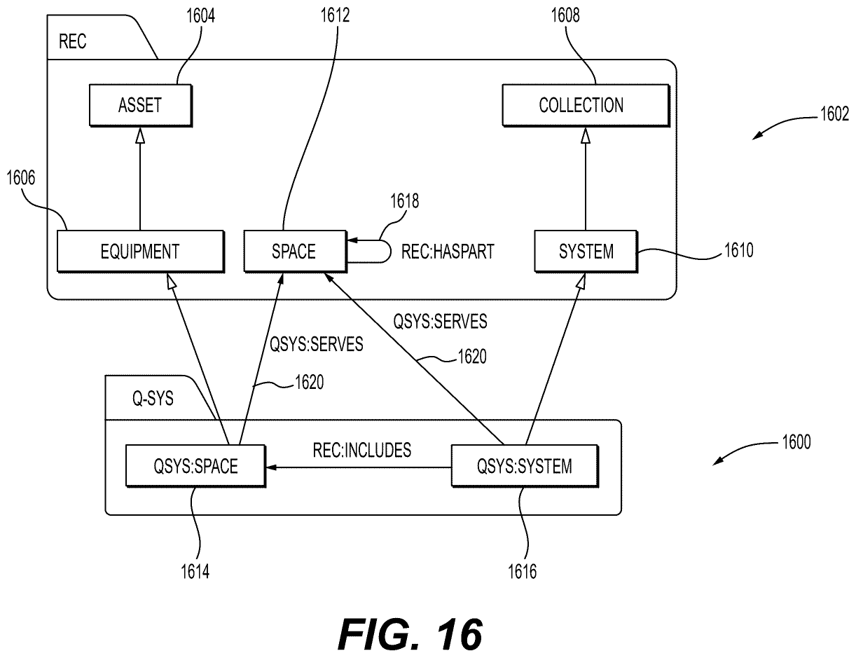

FIG. 16 is a diagram illustrating an example of how an ontology describing the AVC system 1600 (illustrated as a folder) may interact or be linked with another existing ontology, for example, a real-estate core (REC) 1602 (illustrated as a folder). As indicated above, the REC is an existing ontology that describes constituents of any type of real estate, such as a building, room, floor, ceiling, and so on, and/or any smart infrastructure (a smart HVAC system) or mechanical, electrical, or computing components thereof, such as a security system, fire alarm system, and so on.

The AVC system ontology 1600 describes the inventory items, controls, and components of the AVC system, as has been described above. The REC ontology 1602 describes the buildings and structures and the things that go the buildings and structures. FIG. 16 graphical illustrates that the AVC system ontology 1600 and the REC ontology 1602 can be linked together.

As shown in the example ontologies in FIG. 16, the REC ontology 1602 includes specific models such as, for example, an asset model 1604, an equipment model 1606, a collection model 1608, a system model 1610, and a space model 1612. The REC ontology 1602 diagram shows the REC models linked by arrows. For example, the collection model 1608 may represent a grouping of objects and the system model 1610 may be connected to the collection model 1608 by an open arrow that represents that system model 1610 is defined by elements from the collection model 1608 (e.g., an inheritance relationship or parent-child relationship). Similarly, the asset model 1604 may be a grouping of assets, some of which may be equipment. The equipment model 1606 may be connected to the asset model 1604 by an open arrow indicating that equipment model 1606 is defined by elements from the asset model 1604 (e.g., an inheritance relationship or parent-child relationship).

The AVC system folder ontology 1600 may include a space model 1614 and a system model 1616. The example diagram shows the space model 1614 being connected to the equipment model 1606 and to the space model 1612 of the REC ontology 1602 and the system model 1616 being connected to the space model 1612 and the system model 1610 of the REC ontology 1602. Thus, the diagram illustrates that the space model 1614 may interact with or be associated with the equipment model 1606 and to the space model 1612, and that the system model 1616 may interact with or be associated with the space model 1612 and the system model 1610 of the REC ontology. For example, the space model 1614 of the AVC system may utilize and extend (e.g., adding elements or functionality to) the equipment model 1606.

FIG. 16 further provides some additional detail regarding the models and the interaction between the models. For example, the FIG. 16 includes arrow 1618 which indicates that the space model 1612 of the REC “hasPart”, which may indicate that the spaces within the space model 1612 may have subparts or subspaces (e.g., a building may have floors in the building, each floor may have rooms, etc.). As another example, the diagram includes arrows 1620 which indicates that the space model 1612 of the REC “serves” the space model 1614 and the system model 1616 of the AVC system, which indicates that the space model 1612 of the REC provides functionality for the space model 1614 and the system model 1616 of the AVC system. FIG. 16, therefore, is a high-level diagram showing the AVC system using another ontology (i.e., the REC) and that they are linked, operating together, and sharing information.

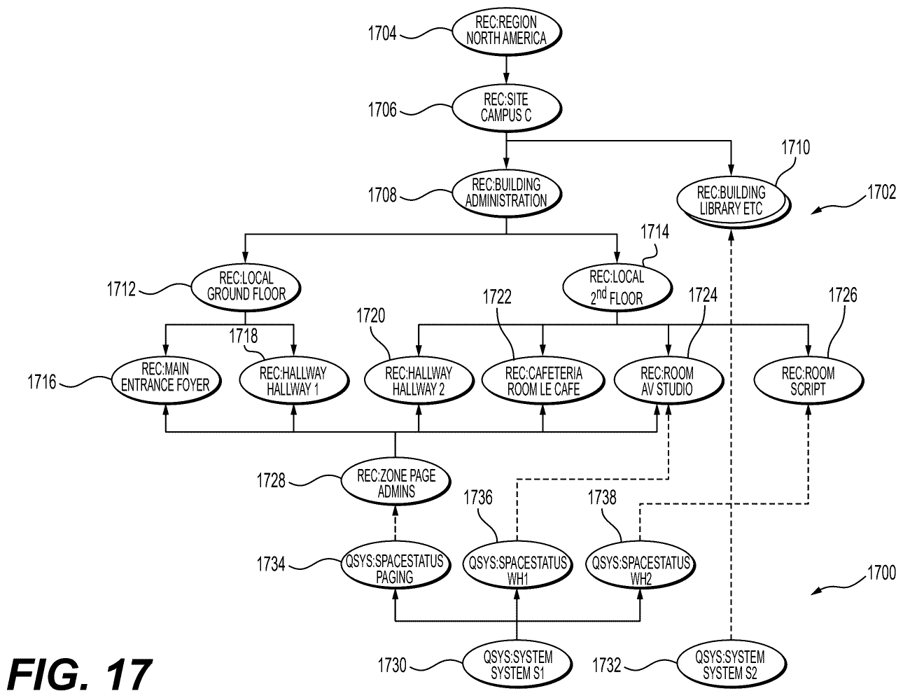

FIG. 17 is a diagram illustrating how an example ontology describing one more AVC systems may interact with or be linked with another existing ontology, for example, an example real-estate core (REC) ontology 1702. As shown, the example REC ontology 1702 may include, at its broadest, a region model 1704 (e.g., North America) and a site model 1706 (e.g., Campus C) that is a subpart of region model 1704. The REC ontology 1702 may further include one or more building models that are subparts of the site model 1706. The illustrated example may include a first building model 1708 (e.g., Administration building), and a second building model 1710 that may model a group of multiple buildings (e.g., Library, etc.).

The REC ontology 1702 may further include one or more level models that are subparts of the first building model 1708. The illustrated example may include a first level model 1712 (e.g., Ground Floor) and a second level model 1714 (e.g., Second Floor). The REC ontology 1702 may further include one or more space models that are subparts of the level models 1712, 1714. In the illustrated example, the space models may include a main entrance model 1716, a first hallway model 1718 as subparts of the first level model 1712 and a second hallway model 1720, a cafeteria room model 1722, a first meeting room model 1724, and a second meeting room model 1726 as subparts of the second level model 1714.

In some implementations, one or more space models, level models, building models, etc., may be grouped in one or more zone models. For example, in the illustrated example, the main entrance model 1716, the first hallway model 1718, the second hallway model 1720, the cafeteria room model 1722, and the first meeting room model 1724 may be subparts of a zone model 1728 (e.g., Page Admins).

This REC ontology 1702 may be linked to and interact with the AVC system ontology 1700. For example, in the illustrated example, the AVC system ontology 1700 may include a first system model 1730 and a second system model 1732. The two system models 1730, 1732 may represent separate ontologies for separate AVC systems or may represent subparts of the same AVC system. The AVC ontology 1700 may further include one or more space status models or controls that are subparts of the system models 1730, 1732. In the illustrated example, the AVC ontology 1700 may include a first space status model or control 1734 (e.g., paging status) associated with the status of the paging system for the spaces associated with the zone model 1728, a second space status model or control 1736 associated with the status of the paging system for the first meeting room, and a third space status model 1738 associated with the status of the paging system for the second meeting room.

As shown in FIG. 17, the second system model 1732 may be linked to the second building model 1710 while the first system model 1730 may be linked to the first building model 1708. Thus, FIG. 17 illustrates the hierarchical structure of both the REC ontology and the AVC ontology and how the ontologies interact. It will be understood that the specific hierarchy of models and model types in the REC and the AVC may vary in different implementations of the AVC system.

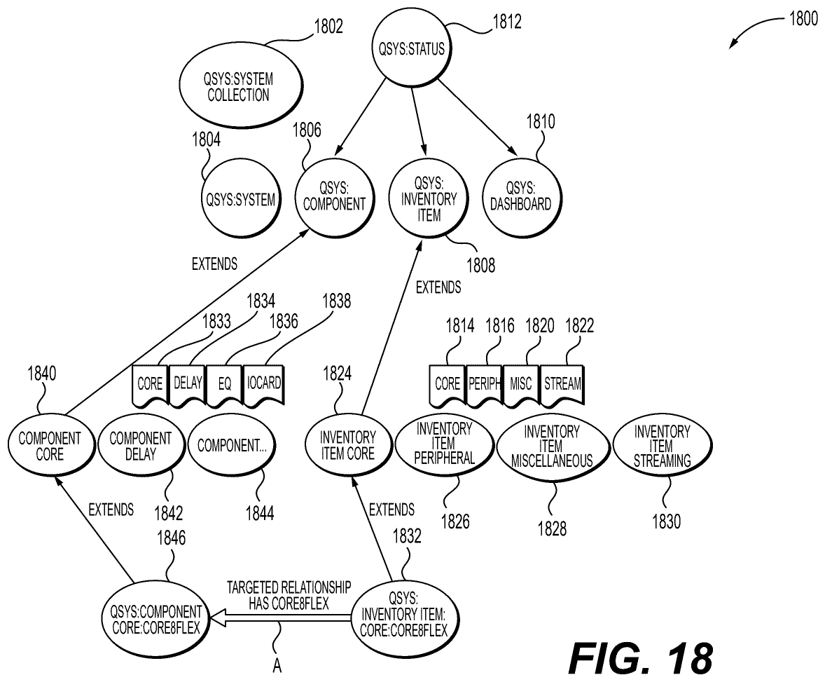

FIG. 18 is a diagram illustrating the relationships between inventory items of an example AVC system 1800 and at least one of their components (e.g., a status component). For example, FIG. 18 illustrates the AVC system having a system collection model 1802, a system model 1804, a system component model 1806, a system inventory item model 1808, and a system dashboard model 1810. FIG. 18 further indicates the system status 1812 is a component within each of these models. Regarding the system inventory item model 1808, inventory items of the system may include, for example, a processor core 1814, system peripherals 1816, system streaming 1818, miscellaneous items 1820, stream 1822, etc. The example of FIG. 18 illustrates that the inventory item model 1808 may be extended by an inventory item core model 1824. Models also may exist for other inventory items, such as an inventory item peripheral model 1826, an inventory item miscellaneous model 1828, and an inventory item streaming model 1830, etc.

In the example of FIG. 18, the inventory item core model 1824 may be extended by an inventory item Core8Flex model 1832. Thus, the right side of the diagram of FIG. 18 shows how the system is interconnected (i.e., how the individual inventory item models extend from a generic system inventory item model).

The left side of the diagram of FIG. 18 illustrates the properties, controls, and details of the inventory items and the design that the inventory items will run. For example, regarding the system component model 1806. The system component may be, for example, a status component. There may also be other components, such as components related to signal processing, such as core component 1833, delay component 1834, equalizer component 1836, iocard component 1838, etc. As shown in FIG. 18, the system component model 1806 may be extended by a component core model 1840. Similarly, the delay component 1834 may be extended by a component delay model 1842, the equalizer component 1836 may be extended by an equalizer component model 1844, and so forth. The component core model 1840 may further be extended by a component Core8Flex model 1846.

Thus, FIG. 18 illustrates that the generic system component model 1806 may be extended to a more specific component Core8Flex model 1846. FIG. 18 further illustrates that there is a relationship, as shown by arrow A, between the Inventory item Core8Flex model 1832 and the component Core8Flex model 1846, representing, for example, the status component (from the system components) of the Core8Flex (from the inventory items).

### Additional Implementations

Additional implementations of the present disclosure are described below.

In some embodiments, a method of utilizing digital twins in a cloud-based audio, video, and control (AVC) system may include defining a device configuration of a physical device of the AVC system, wherein the device configuration includes at least one of a setting, a parameter, a state, a software, a firmware, or a signal routing.

In some embodiments, the method may include creating, via a server of a cloud platform, a digital twin of the physical device based on the device configuration.

In some embodiments, the method may include synchronizing, by the server, the digital twin to the physical device such that the digital twin receives, and stores device information associated with the physical device, wherein the device information includes at least one of a setting, a parameter, operational data, a state, a status, or a health indication.

In some embodiments, the method may include analyzing, by the server via a web application, the device information stored by the digital twin to identify if the physical device is performing satisfactorily.

In some embodiments, the method may include presenting, via a computing device, an output from the web application indicative of the performance of the physical device.

In some embodiments, the method may include communicatively connecting a replacement physical device to the server of the cloud platform.

In some embodiments, the method may include deploying, by the server, the device configuration stored by the digital twin to the replacement device.

In some embodiments, the method may include synchronizing, by the server, the digital twin to the replacement physical device such that the digital twin receives and stores device information associated with the replacement physical device, wherein the device information includes at least one of a setting, a parameter, operational data, a state, a status, or a health indication.

In some embodiments, the method may include, in response to an output from the web application indicating that the physical device is not performing satisfactorily, creating a virtual device based on the device configuration stored by the digital twin.

In some embodiments, the method may include routing at least one of a video signal, an audio signal, or a control signal to the virtual device.

In some embodiments, the method may include processing, by the server via the virtual device, the at least one of the video signal, the audio signal, or the control signal such that the virtual device is replacing a processing task of the physical device.

In some embodiments, the physical device may be at least one of a camera, a microphone, a processor core, or a soundbar.

In some embodiments, the device information associated with the physical device may include at least one of operational, real-time data, historical data, configuration data, maintenance and health records, external and environmental data, performance metrics, lifecycle data, sensory data, software/firmware versions, connectivity and network data, or operational guidelines and constraints

In some embodiments, an audio, video, and control system may include a physical device communicatively connected to a server on a cloud platform and a digital twin of the physical device residing on the cloud platform.

In some embodiments, the digital twin is synchronized with the physical device to contain configuration information of the physical device, wherein the digital twin, wherein the configuration information includes at least one of a setting, a parameter, a state, a software, a firmware, or a signal routing.

In some embodiments, the audio, video, and control system may include a memory coupled to the server comprising instructions executable by the server.

In some embodiments, the server may be operable when executing the instructions to analyze, by the server via a web application, the device information stored by the digital twin to identify if the physical device is performing satisfactorily.

In some embodiments, the server may be operable when executing the instructions to present, via a computing device, an output from the web application indicative of the performance of the physical device.

In some embodiments, the server may be operable when executing the instructions to deploy, by the server, the device configuration stored by the digital twin to a replacement physical device communicatively connected a replacement to the server.

In some embodiments, the server may be operable when executing the instructions to synchronize, by the server, the digital twin to the replacement physical device such that the digital twin receives and stores device information associated with the replacement physical device, wherein the device information includes at least one of a setting, a parameter, operational data, a state, a status, or a health indication.

In some embodiments, the server may be operable when executing the instructions to, in response to an output from the web application indicating that the physical device is not performing satisfactorily, create a virtual device based on the device configuration stored by the digital twin.

In some embodiments, the server may be operable when executing the instructions to route at least one of a video signal, an audio signal, or a control signal to the virtual device.

In some embodiments, the server may be operable when executing the instructions to process, by the server via the virtual device, the at least one of the video signal, the audio signal, or the control signal such that the virtual device is replacing a processing task of the physical device.

In some embodiments, the physical device may be at least one of a camera, a microphone, a processor core, or a soundbar.

In some embodiments, the device information associated with the physical device may include at least one of operational, real-time data, historical data, configuration data, maintenance and health records, external and environmental data, performance metrics, lifecycle data, sensory data, software/firmware versions, connectivity and network data, or operational guidelines and constraints.

In some embodiments, an audio, video, and control system may include a physical device communicatively connected to a server on a cloud platform and a digital twin of the physical device that resides on the cloud platform. In some embodiments, the physical device may run a software program.

In some embodiments, the digital twin may be synchronized with the physical device to contain configuration information of the physical device. In some embodiments, the configuration information may include at least one of a setting, a parameter, a state, a software, a firmware, or a signal routing.

In some embodiments, the audio, video, and control system may include a memory coupled to the server comprising instructions executable by the server.

In some embodiments, the server may be operable when executing the instructions to create, in the cloud platform, a virtual device of the physical device based on the configuration information of the physical device stored in the digital twin.

In some embodiments, the server may be operable when executing the instructions to emulate, in the cloud platform via the virtual device, signal processing and operation of the physical device with an update of the software program, wherein emulating includes receiving and processing, by the virtual device, at least one of an audio signal, a video signal or a control signal.

In some embodiments, the server may be operable when executing the instructions to deploy the update of the software program to the physical device.

In some embodiments, the physical device may be at least one of a camera, a microphone, or a soundbar.

In some embodiments, the server may be operable when executing the instructions to verify, by a verifier module of the server, that the virtual device is acceptably processing the at least one of the audio signal, the video signal, or the control signal.

In some embodiments, the server may be operable when executing the instructions to send an alert to a user device in the form of an audio or visual signal when the update of the software program is available.

In some embodiments, the server may be operable when executing the instructions to receive a request to update the software program.

In some embodiments, the server may be operable when executing the instructions to, upon receiving the request to update the software program, to update the configuration information of the physical device stored in the digital twin.

In some embodiments, the server may be operable when executing the instructions to for utilizing a perpetual virtual device of physical device of a cloud-based audio, video, and control (AVC) system, where the physical device is communicatively connected to a server of a cloud platform, may include synchronizing, by the server, the digital twin to the physical device such that the digital twin stores configuration information associated with the physical device and receives telemetry data from the corresponding device

In some embodiments, the method may include creating in the cloud platform, by the server, a virtual device based on configuration information stored in the digital twin of the physical device.

In some embodiments, the method may include emulating, in the cloud platform via the virtual device, signal processing and operation of the physical device, wherein emulating includes receiving and processing, by the virtual device, at least one of an audio signal, a video signal, or a control signal.

In some embodiments, the virtual device may be configured to continuously emulate the signal processing and operation of the physical in the cloud platform regardless of whether the AVC system is operating.

In some embodiments, the method may include verifying, by a verifier module of the server, that the virtual device is acceptably processing the at least one of the audio signal, the video signal, or the control signal.

In some embodiments, the method may include presenting, via a computing device, an output from the web application indicative of the performance of the virtual device.

In some embodiments, the physical device is at least one of a camera, a microphone, a processor core, or a soundbar.

In some embodiments, the method may include storing, on the cloud platform, data from the perpetual virtual device indicative of the signal processing and operational performance of the virtual device over time.

In some embodiments, a method of configuring an audio, video, and control (AVC) system may include receiving an AVC system design, wherein the AVC system is configured to include a physical device.

In some embodiments, the AVC system design may include a device configuration that may include at least one of a setting, a parameter, a state, a software, a firmware, or a signal routing.

In some embodiments, the method may include creating, via the server, a digital twin of the physical device based on the device configuration.

In some embodiments, the method may include creating in the cloud platform, by the server, a virtual device based on information stored in the digital twin of the physical device.

In some embodiments, the method may include emulating, by the virtual device, signal processing and operation of the corresponding physical device to predict behavior and operation of the corresponding physical device, wherein emulating includes receiving and processing, by the virtual device, at least one of an audio signal, a video signal, or a control signal.

In some embodiments, the method may include verifying, by a verifier module of the server, that the virtual device is acceptably processing the at least one of the audio signal, video signal, or control signal.

In some embodiments, the method may include transferring, by the server, the device configuration of the virtual device to the physical device.

In some embodiments, the physical device may be one of a camera, a microphone, a soundbar, and a processor core.

In some embodiments, receiving an AVC system design may further include importing a preexisting AVC design from a source external to the server.

In some embodiments, receiving an AVC system design may further include entering the AVC system design into a web application associated with the cloud platform.

In some embodiments, the method may include transferring, by the server, the device configuration of the virtual device to the physical device, further comprises communicatively connecting the physical device to the server.

In some embodiments, the at least one audio signal, video signal, and control signal may be a previously recorded or streaming signal.

In some embodiments, the method may include retrieving from a memory associated with cloud platform, the at least one audio signal, video signal, and control signal.

In some embodiments, the verifier module may be configured to present, via a computing device, an output from the virtual device for inspection.

In some embodiments, the verifier module may be further configured to receive, via the computing device, a user input indicative of whether the virtual device has acceptably processed the at least one of the audio signal, the video signal, or control signal.

In some embodiments, the method may include synchronizing, by the server, the digital twin to the physical device such that at least one of the digital twin retrieves operational data and configuration data associated with the physical device and an operational or configuration data change at the digital twin is transferred to the physical device.

In some embodiments, an audio, video, and control system may include a physical device communicatively connected to a server of a cloud platform and a memory coupled to the server comprising instructions executable by the server.

In some embodiments, the server may be operable when executing the instructions to receive an AVC system design that includes a device configuration, wherein the device configuration includes at least one of a setting, a parameter, a state, a software, a firmware, or a signal routing.

In some embodiments, the server may be operable when executing the instructions to create in the cloud platform, by the server, a digital twin of the physical device based on the device configuration.

In some embodiments, the server may be operable when executing the instructions to create in the cloud platform, by the server, a virtual device based on information stored in the digital twin of the physical device.

In some embodiments, the server may be operable when executing the instructions to emulate, by the virtual device, signal processing and operation of the corresponding physical device to predict behavior and operation of the corresponding physical device, wherein emulating includes receiving and processing, by the virtual device, at least one of an audio signal, a video signal, or a control signal.

In some embodiments, the server may be operable when executing the instructions to verify, by a verifier module of the server, that the virtual device is acceptably processing the at least one of the audio signal, the video signal, or the control signal.

In some embodiments, the server may be operable when executing the instructions to transfer, by the server, the device configuration of the virtual device to the physical device.

In some embodiments, the physical device may be one of a camera, a microphone, a soundbar, and a processor core.

In some embodiments, the server may be operable when executing the instructions to import a preexisting AVC design from a source external to the server.

In some embodiments, the server may be operable when executing the instructions to receive the AVC system design via input into a web application associated with the cloud platform.

In some embodiments, the at least one audio signal, video signal, and control signal may be a previously recorded or streaming signal.

In some embodiments, the audio, video, and control system may further include a cloud database associated with the cloud platform and configured to store the at least one audio signal, video signal, and control signal.

In some embodiments, the verifier module may be operable to present, via a computing device, an output from the virtual device for inspection.

In some embodiments, the audio, video, and control system verifier module may be further configured to receive, via the computing device, a user input indicative of whether the virtual device has acceptably processed the at least one of the audio signal, video signal, or control signal.

In some embodiments, the digital twin of the physical device may be configured to synchronize to the physical device such that the digital twin receives operational data and configuration data associated with the physical device.

In some embodiments, an audio, video, and control system may include a physical device communicatively connected to a server of a cloud platform and a memory coupled to the server comprising instructions executable by the server.

In some embodiments, the server may be operable when executing the instructions to receive an AVC system design that includes a device configuration and a processor core configuration, wherein the device configuration and the processor core configuration each include at least one of a setting, a parameter, a state, a software, a firmware, or a signal routing.

In some embodiments, the server may be operable when executing the instructions to create in the cloud platform, by the server, a digital twin of the physical device based on the device configuration and of the processor core based on the processor core configuration.

In some embodiments, the server may be operable when executing the instructions to create in the cloud platform, by the server, a virtual device based on information stored in the digital twin of the physical device.

In some embodiments, the server may be operable when executing the instructions to create in the cloud platform, by the server, a virtual processor core based on information stored in the digital twin of the processor core.

In some embodiments, the server may be operable when executing the instructions to emulate, by the virtual device and the virtual processor core, signal processing and operation of the corresponding physical device to predict behavior and operation of the corresponding physical device, wherein emulating includes receiving and processing, by the virtual device and the virtual processor core, at least one of an audio signal, a video signal, or a control signal.

In some embodiments, the server may be operable when executing the instructions to verify, by a verifier module of the server, that the virtual device and the virtual processor core are acceptably processing the at least one of the audio signal, video signal, or control signal.

In some embodiments, the server may be operable when executing the instructions to transfer, by the server, the device configuration of the virtual device to the physical device.

In some embodiments, the virtual core may be configured to process at least one of audio signals, video signals, or control signals captured by the physical device.

In some embodiments, predetermined types of signals from the physical device may be routed to and processed within the cloud platform by the virtual core while types of signals not of the predetermined types are routed and processed by a physical core.

In some embodiments, a determination of a latency of routing signals between the cloud platform and the physical device may be used to select which types of signals are routed to and processed by the virtual core.

In some embodiments, the AVC system may be configured to allow manual adjustment of which types of signals are processed by either of the physical core or the virtual core 250.

In some embodiments, available computing resources required to process the signals from the physical device may be used to select which types of signals are routed to and processed by the virtual core.

### INDUSTRIAL APPLICABILITY

The integration of virtual and physical devices into a cloud-based AVC system can offer a streamlined, efficient, and cost-effective approach to system design, testing, and deployment. With virtual devices, users may iterate and refine the system virtually before investing in and deploying physical devices. Thus, embodiments of the AVC system not only economizes the development process but can also provide a flexible, risk-reduced environment for creating sophisticated, well-tuned AVC systems. An AVC digital twin may represent a digital replica of an audio, video, and control (AVC) device. This digital copy may mirror the features, configurations, and status of its physical counterpart, facilitating seamless interaction, analysis, and control in a virtual space.

Design Phase: The cloud-based AVC with digital twins and/or virtual devices disclosed herein may be an effective tool during the iterative design phase for the AVC system. This virtual environment may enable a user to conceptualize, design, and modify the AVC system, via a web application, without the initial investment in physical devices.

Testing and Tuning: In some embodiments, users can perform rigorous testing and tuning processes in this virtual space, refining the system's performance and ironing out issues before any physical implementation occurs.

Cost-effective: In some embodiments, the disclosed AVC systems may reduce upfront costs as there is little to no need to purchase physical devices during the design and testing phases. Thus, the AVC systems may allow for economic efficiency and risk mitigation, as users can experiment and iterate without financial constraints of physical hardware.

Proof of Concept: In some embodiments, the AVC systems may support the development of proof of concept and prototype systems, enabling users to visualize and understand the proposed AVC system's functionality and potential before making substantial investments.

Functional Testing: In some embodiments, the virtual devices may handle both live and recorded AVC inputs, providing a versatile testing environment, which may allow for conducting various tests, simulations, and analyses under different conditions and scenarios.

Output Monitoring: In some embodiments, the AVC systems may allow users to monitor the outputs of the virtual devices live, offering instant feedback and real-time data during testing. In some embodiments, outputs may be recorded for more detailed post-test analysis and review.

Rapid Prototyping: The use of digital twins and virtual devices may accelerate the prototyping process, allowing for quick adjustments, modifications, and improvements to the AVC system's design.

Risk Reduction: With the ability to test and refine in a virtual space, the risks associated with testing and refining physical devices may be significantly minimized. For example, predictability of a software upgrade may be increased if the software upgrade is emulated by a virtual device using information of a physical device stored in a digital twin. Further, regularly scheduled emulation of testing for security vulnerabilities on any number of virtual devices or virtual AVC systems may be performed. Still further, the system may predict how the physical device may integrate or interface with other systems or components. In addition, virtual emulation of a physical device or system may be scaled up or down or altered to emulate different scenarios.

Flexible Testing Environment: The emulation of live and recorded inputs can provide a robust and flexible testing environment that allows for addressing and evaluating different use case scenarios and operational conditions.

Always Online: In some embodiments, the AVC digital twin and/or the virtual device can operate in a cloud-based environment, ensuring consistent online presence, accessibility, and data syncing.

External Interaction: In some embodiments, control, analysis, or interaction with the AVC device may occur via its digital twin. This mechanism may allow for secure, streamlined, and efficient device management without directly accessing the physical hardware.

Offline Support: In some embodiments, even when the AVC device is offline, the digital twin may remain active. Users may implement configuration changes, which are stored and later synchronized when the device resumes connection.

Single Source of Truth: In some embodiments, the digital twin in the AVC system may hold the complete configuration details of the AVC device. Thus, the digital twin may act as the definitive reference point for device settings, status, operational parameters, and so on.

Continuous Sync: In some embodiments, the AVC device can maintain perpetual synchronization with its digital twin, ensuring real-time data accuracy and consistency between the digital twin and its virtual and physical counterparts.

Offline Data Storage: In some embodiments, for offline devices, a status change or configuration adjustment may be stored locally. Upon reconnection, these changes can be uploaded and synchronized with the digital twin. For example, within the context of edge computing (e.g., edge computing as is commonly known in the art), the offline device may be functioning properly yet may not be connected to a cloud platform. In this example, status changes, settings, parameters, configurations, and so on of the offline device may be adjusted, for example, automatically or manually by a user. Any status changes, settings, parameters, configurations may be stored locally and then, upon reconnection to the cloud platform, the offline device may synchronize and upload the status changes, settings, parameters, configurations to the digital twin.

Minimal User Intervention: In cases where an AVC device malfunctions, the AVC device can be replaced efficiently with a new unit. The digital twin facilitates this process by providing the necessary configurations and settings, minimizing the setup time and user involvement required.

Data Repository: In some embodiments, the AVC digital twin may serve as a comprehensive data repository, capturing and storing the historical data of the device. This archive may include device performance metrics, operational history, configuration changes over time, and so on.

Trend Analysis: In some embodiments, with access to historical data, users may perform trend analysis to understand the device's operational patterns, behaviors, and performance fluctuations. This insight may be used for predictive maintenance, long-term planning, and decision-making processes.

Remote Management: In some embodiments, a user may remotely monitor, analyze, and adjust AVC devices through a digital twin via a web application, reducing the need for physical interaction and onsite management.

Predictive Maintenance: In some embodiments, the accumulation of historical data may allow for the identification of potential issues or failures before they occur, enabling proactive maintenance and minimizing downtime.

Efficient Configuration: The digital twin may simplify device setup and configuration processes, particularly when replacing hardware or adjusting device settings.

Technical Improvement: The cloud-based AVC with digital twins and/or virtual devices disclosed herein may provide technical improvements of the physical devices within the system and the system as a whole. For example, in some embodiments, using a virtual device to emulate a physical device of the system may allow for testing and refinement of the configuration of the physical device, which once deployed to the physical device, may improve its performance. As another example, in some embodiments, emulating a software upgrade on a counterpart virtual device may allow for testing of the software upgrade prior to deployment to the physical device, thus avoiding potential system performance issues associated with a software upgrade. As another example, in some embodiments, processing in a virtual device some or all of the tasks of a physical device may improve the performance of the physical device, the overall system, or both, such as for example, where there is performance degradation of the physical device, latency issues with routing signals, insufficient computing resources, etc. As another example, in some embodiments, data stored in a digital twin may be analyzed and presented in a manner that allows for the health, reliability, usage, and/or operational status of the physical device and the space in which the device is located to be determined, thus allowing for a better understanding of where improvements may be implemented. For example, analysis of data stored in a digital twin may identify that a physical device is not performing satisfactorily. In response, a virtual device may be created to process some or all of the tasks of the physical device and/or the device configuration stored by the digital twin may be deployed to a replacement device, thus allowing for improved system performance.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the embodiments described. The terminology used herein was chosen to best explain the principles of the embodiments, the practical application or technical improvement over technologies found in the marketplace, or to enable others of ordinary skill in the art to understand the embodiments disclosed herein.

As used herein, the term “component” is intended to be broadly construed as hardware, firmware, or a combination of hardware and software. It will be apparent that systems and/or methods described herein may be implemented in different forms of hardware, firmware, and/or a combination of hardware and software. The actual specialized control hardware or software code used to implement these systems and/or methods is not limiting of the implementations. Thus, the operation and behavior of the systems and/or methods are described herein without reference to specific software code—it being understood that software and hardware can be used to implement the systems and/or methods based on the description herein.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Although particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”).

What is claimed is:

1. A method of monitoring behavior of an audio, video, and control system, the method comprising:
communicatively connecting one or more devices of the audio, video, and control system to a server of a cloud platform;
creating, by the server, one or more device digital twins of the one or more devices;
synchronizing, by the server, each of the one or more device digital twins to a corresponding device of the one or more devices such that each of the one or more device digital twins receives data from the corresponding device;
creating, by the server, one or more space digital twins of one or more physical spaces that the one or more devices are located in;
synchronizing, by the server, each of the one or more space digital twins to a corresponding physical space such that each of the one or more space digital twins receives data from one or more of the devices located within corresponding physical space;
analyzing, by the server, the data associated with the one or more devices and the one or more physical spaces to create an output indicative of at least one of a health of one or more of the devices, a reliability of one or more of the devices, a usage of the physical space, or an operational status of the physical space; and
causing, by the server, the output to be presented to a computing device, wherein the output includes at least one of a representation of the health of the device, a representation of the reliability of the device, a representation of the usage of the physical space, or a representation of the operational status of the physical space.

2. The method according to claim 1, further comprising retrieving, by the server, historical data associated with the one or more devices and the one or more physical spaces from a cloud database for analysis.

3. The method according to claim 1, wherein the data associated with the one or more devices located in one of the physical spaces includes at least one of space occupancy, space people count, space capacity, organization average occupancy, organization average people count, organizational average percent of volume, cloud platform average occupancy, cloud platform average people count, or cloud platform average percent of capacity.

4. The method according to claim 1, wherein the data associated with the one or more devices includes at least one of system alerts, system average alerts, organization average system alerts, or space business hours.

5. The method according to claim 1, wherein the one or more physical spaces include one or more of a geographical region, a building, a floor of the building, a room, a ceiling, and a wall.

6. The method according to claim 1, further comprising receiving, by the server, ontological data from the one or more devices, and creating, by the server, an ontological framework with classifications of the ontological data of at least one of assets, systems and organization of systems, geographical regions, people and organizations of people, or monitor points and controls.

7. The method according to claim 6, further comprising causing, by the server, a representation of the ontological framework to be presented to a computing device.

8. The method according to claim 7, wherein the representation of the ontological framework includes a knowledge graph.

9. The method according to claim 1, further comprising creating, by the server, a map displaying markers indicating a location of one or more of the physical spaces and a status of the one or more devices in the one or more physical spaces and causing the map to be presented to a computer device.

10. The method according to claim 9, wherein the map displays one of a region, a building, a floor of the building, or a room.

11. The method according to claim 1, further comprising integrating, by the server, the one or more device digital twins with a preexisting ontology stored in a database on the cloud platform.

12. An audio, video, and control system, comprising:
one or more devices communicatively connected to a system processor core, wherein the one or more devices and the system processor core are communicatively connected to a server on a cloud platform, wherein the one or more devices include at least one of a camera, a microphone, a soundbar, or a processor;
one or more device digital twins of the one or more devices, wherein the one or more device digital twins are synchronized with the one or more devices to collect data associated with the one or more devices, wherein the one or more device digital twins reside on the cloud platform;
one or more space digital twins of one or more physical spaces that the one or more devices are located in, wherein each of the one or more space digital twins is synchronized with the one or more devices located within the corresponding physical space to collect the data associated with the one or more devices, wherein the one or more space digital twins reside on the cloud platform;
a memory coupled to the server comprising instructions executable by the server, the server operable when executing the instructions to:
create one or more device digital twins of the one or more devices;
synchronize each of the one or more device digital twins to a corresponding device of the one or more devices such that the one or more device digital twins receive data associated with the one or more devices;
create one or more space digital twins of one or more physical spaces that the one or more devices are located in;
synchronize each of the one or more space digital twins to one or more of the devices that are located in the corresponding physical space such that the one or more space digital twins receive data associated with the one or more devices;
analyze the data associated with the one or more devices and the one or more physical spaces to create an output indicative of at least one of a health of one or more of the devices, a reliability of one or more of the devices, a usage of the physical space, or an operational status of the physical space; and
cause the output to be presented to a computing device, wherein the output includes at least one of a representation of the health of the device, a representation of the reliability of the device, a representation of the usage of the physical space, or a representation of the operational status of the physical space.

13. The audio, video, and control system according to claim 12, wherein the server is operable when executing the instructions to retrieve historical data associated with the one or more devices and the one or more physical spaces from a cloud database for analysis.

14. The audio, video, and control system according to claim 12, wherein the data associated with the physical space of the one or more devices includes at least one of space occupancy, space people count, space capacity, organization average occupancy, organization average people count, organizational average percent of volume, cloud platform average occupancy, cloud platform average people count, or cloud platform average percent of capacity.

15. The audio, video, and control system according to claim 12, wherein the data associated with the one or more devices includes at least one of system alerts, system average alerts, organization average system alerts, or space business hours.

16. The audio, video, and control system according to claim 12, wherein the one or more physical spaces include one or more of a geographical region, a building, a floor of the building, a room, a ceiling, and a wall.

17. The audio, video, and control system according to claim 12, wherein the server is operable when executing the instructions to receive ontological data from the one or more devices.

18. The audio, video, and control system according to claim 17, wherein the server is operable when executing the instructions to create an ontological framework with classifications of the ontological data of at least one of assets, systems and organization of systems, geographical regions, people and organizations of people, or monitor points and controls.

19. The audio, video, and control system according to claim 18, wherein the server is operable when executing the instructions to cause a representation of the ontological framework to be presented to a computing device.

20. The audio, video, and control system according to claim 19, wherein the representation of the ontological framework includes a knowledge graph.

21. The audio, video, and control system according to claim 12, wherein the server is operable when executing the instructions to create a map displaying markers indicating a location of one or more of the physical spaces and an operational status of the one or more devices in the one or more physical spaces and to cause the map to be presented to a computer device.

22. The audio, video, and control system according to claim 21, wherein the map displays one of a region, a building, a floor of the building, or a room.

23. The audio, video, and control system according to claim 12, wherein the server is operable when executing the instructions to integrate the one or more device digital twins, with a preexisting ontology stored in a database on the cloud platform.

24. An audio, video, and control system, comprising:
one or more devices communicatively connected to a server on a cloud platform, wherein the one or more devices include at least one of a camera, a microphone, a soundbar, or a processor;
one or more device digital twins of the one or more devices, wherein the one or more device digital twins are synchronized with the one or more devices to collect data associated with the one or more devices, wherein the one or more device digital twins reside on the cloud platform;
a memory coupled to the server comprising instructions executable by the server, the server operable when executing the instructions to:
synchronize, by the server, each of the one or more device digital twins to a corresponding device of the one or more devices such that each of the one or more device digital twins receives data from the corresponding device;
receive, by the one or more device digital twins via the server, ontological data from the one or more devices;
integrate, by the server, the one or more device digital twins with an existing real-estate core ontology stored on the cloud platform, wherein the real-estate core ontology describes spaces in which the one or more devices are located in;
create, by the server, an ontological framework based on the ontological data received from the one or more device digital twins and ontological data from the real-estate core ontology; and
cause, by the server, a representation of the ontological framework to be presented to a computing device.

25. The audio, video, and control system according to claim 24, wherein the representation of the ontological framework includes a knowledge graph.

26. The audio, video, and control system according to claim 24, wherein the representation of the ontological framework includes a topological representation of at least one a grouping and classification of one or more AVC systems; a grouping and classification of an owner, administrator, or user of each of the one or more AVC systems; and access management to each of the one or more AVC systems.

27. The audio, video, and control system according to claim 24, wherein the representation includes a world-view representation including at least one of geographical regions, sites, buildings, levels, rooms, or zones in which the one or more devices are located.
